(19) United States
(12) Patent Application Publication
(10) Pub. No.: US 2025/0007531 A1
(43) Pub. Date: Jan. 2, 2025

(54) CAPACITIVE DIGITAL-TO-ANALOG CONVERTER FOR MULTI-BAND RADIO FREQUENCY COMMUNICATION

(71) Applicant: Intel Corporation, Santa Clara, CA (US)

(72) Inventors: Ofir DEGANI, Haifa (IL); Assaf BEN-BASSAT, Haifa (IL)

(21) Appl. No.: 18/343,822

(22) Filed: Jun. 29, 2023

(51) Int. Cl. H03M 1/46; H03M 1/80

(52) U.S. Cl. CPC H03M 1/468; H03M 1/804

(57) ABSTRACT

Disclosed herein are devices, methods, and systems that relate to wireless communications architectures and, in particular, multi-band radio-frequency circuitry. Disclosed herein is a capacitive digital-to-analog converter (CDAC). The CDAC may include a plurality of circuits configured to receive a digital signal to be converted into an analog signal, wherein each circuit of the plurality of circuits may include: a variable capacitive element; and a driver configured to cause the variable capacitive element to be charged or discharged to convert the received digital signal into the analog signal.

### TECHNICAL FIELD

Various aspects of this disclosure relate to capacitive digital-to-analog converters, digital transmission circuits, and radio communication devices.

### BACKGROUND

Digital transmission (TX) architectures may be preferable for radio telecommunication due to their compactness, especially in terms of the die area, their scalability in advance complementary metal-oxide-semiconductors (CMOS), and improved power efficiency, in particular, due to the use of digital power amplifiers (DPAs). One type of DPAs used in such digital TX architectures is a switched capacitor DPA (SCDPA). SCPDAs may be preferable in various operations due to their high efficiency, low distortion, and reduced size and costs compared to traditional PAs.

An SCDPA may include a switched capacitor network that may be used to convert an input signal to a high-voltage signal, which may be then amplified by a PA stage. The switched capacitor network may include any type of capacitive units as capacitors. In a radio communication circuit architecture configured for multi-band radio frequency (RF) operation, separate DPAs (e.g. SCDPAs) may be employed for different bands of frequencies, since it may be challenging to support multi-band RF operation in an effective manner with desired characteristics.

### BRIEF DESCRIPTION OF FIGURES

In the drawings, like reference characters generally refer to the same parts throughout the different views. The drawings are not necessarily to scale, emphasis instead generally being placed upon illustrating the principles of the disclosure. In the following description, various aspects of the disclosure are described with reference to the following drawings, in which:

FIGS. 1 and 2 depict a general network and device architecture for wireless communications;

FIG. 3 shows an exemplary illustration of various communication elements of an apparatus for a wireless communication device;

FIG. 4 shows an exemplary illustration of a transmit path of an RF transceiver;

FIG. 5 schematically shows an example of an SCDPA;

FIG. 6 illustrates an example of a driver of an SCDPA with 2-level transistor stacking to drive capacitors of an SCDPA cell;

FIG. 7 shows schematically an example of a capacitive RF digital to power converter circuit;

FIG. 8 shows an exemplary graph representative of an approximate relationship between the capacitance of a voltage-controlled capacitive element and Vₜᵤₙₑ voltage of a voltage-controlled capacitive element;

FIG. 9 shows schematically an example of an apparatus of a digital communication circuit;

FIG. 10 is a network diagram illustrating an example network environment including communication devices;

FIG. 11 shows schematically load-pull simulation results obtained with a DPA in accordance with aspects provided herein;

FIG. 12 shows schematically load-pull simulation results obtained with a DPA in accordance with aspects provided herein;

FIG. 13 shows schematically load-pull simulation results obtained with a DPA in accordance with aspects provided herein; and

FIG. 14 shows schematically frequency response graphs of a DPA in accordance with aspects provided herein.

### DESCRIPTION

PAs may be used in RF circuits to provide amplification to communication signals. In DTX architectures, PAs may be employed by DPAs such as SCDPAs. An SCDPA may include a switched capacitor network that is configured to convert an input signal to a high-voltage, low-current signal. The switched capacitor network may include multiple capacitors and switches that may be selectively controlled to charge and discharge the capacitors. Through control of charging and discharging the capacitors, the output signal may be provided at a desired amplitude or power. A control circuit (e.g. a digital signal processor (DSP)) may be employed for controlling the timing and sequencing of switches. The output of the SCDPA may be provided to the next component/circuit (e.g. a matching network, an antenna interface, an antenna structure).

Conventionally, an SCDPA may be implemented by a segmentation of an array including multiple cells. Each cell may include a capacitor, one or more logic for activating/deactivating the cell, and an inverter to provide inverted signal to the capacitor. The inverter may be to drive the capacitor. The inverter may include transistors (e.g. field effect transistors (FETs)) configured to drive the capacitor. A controller may control operation of the SCDPA. In particular, the controller may control output signal power of the SCDPA by selectively and/or adaptively activating (or selectively and/or adaptively deactivating) the cells. Activated cells may contribute to the power of the output signal, while deactivated cells do not provide any contribution to the power of the output signal. Traditionally, the SCDPA may be configured to provide the output signal to a matching network to filter out generated harmonics and produce an RF output for transmission via one or more antennas.

In recent RF communication architectures, radio communication apparatus and devices may include components to support RF operation in multiple frequency bands to leverage various services and applications. Traditionally, such devices utilize a distinct power amplifier and possibly further components or modules for each designated frequency band, in order to operate within desired or designated characteristics for RF communication. Exemplarily, a Wireless Fidelity (Wi-Fi) communication apparatus may include first one or more DPAs for RF operations according to 2.4 GHz band, second one or more DPAs for RF operations according to 5 GHz band, and third one or more DPAs for RF operations according to 6 GHz band. Such an approach may contribute to an increased complexity, die area, form factor, and subsequently, cost. Moreover, as wireless communication technology now commonly supports mechanisms having an increased complexity than earlier systems, such as Multiple-Input Multiple-Output (MIMO) and carrier aggregation (CA) techniques, the demand of bandwidth for RF operations grows, which may also result in further usage of more power amplifiers, which again increases the above-mentioned challenges. It may be desirable to address these challenges.

Various aspects are provided in the disclosure, which may help to overcome the above-mentioned challenges of providing multi-band RF operation, which the aspects include, in particular, a DTX architecture including an SCDPA. In more detail, the SCDPA may be a fully integrated and complementary metal oxide semiconductor (CMOS) compatible circuit topology. The SCDPA may be configured to operate in a multi-band RF operation. The SCDPA may operate at distinct frequency bands, in which the difference between the frequency bands may be one or more GHz. By extending the bandwidth of operation of traditional RF SCDPAs, the SCDPA proposed herein may cover multi-band RF operation in a single design, thereby saving area and cost.

Aspects provided herein may include use of one or more capacitive digital-to-analog converters (CDACs) including one or more variable capacitive elements (e.g. a tunable capacitor, a variable capacitor, an adjustable capacitance element, a varactor) in one embodiment. In another embodiment, traditionally used fixed capacitive elements (e.g. capacitors with a fixed capacitance) can be implemented. By varying the capacitance of the variable capacitive elements of the CDAC according to desired frequency band within which RF communication signals are to be transmitted, desired DPA characteristics for multi-band RF operations may be obtained. The SCDPA may include the one or more CDACs, and each CDAC may include an array of unit cells, each unit cell including one of the variable capacitive elements.

The variable capacitive elements may be voltage-variable capacitive elements (e.g. voltage-controlled capacitor, voltage-tunable capacitor, voltage-adjustable capacitive element, varactor such as a metal oxide semiconductor (MOS) varactor) for a voltage-controlled operation to change the capacitance. A voltage applied to a terminal coupled to the voltage-variable capacitive elements may cause the change of the capacitance. Aspects may include an apparatus including a voltage supply circuit and a controller to control the capacitance of the voltage-variable capacitive elements. It is to be noted that capacitive elements may be any type of capacitive units having a capacitance (e.g. intrinsic capacitance) that may be designated.

Furthermore, in some aspects the one or more CDACs may be connectable to a matching network including one or more transformers, and the voltage-variable capacitive elements may be coupled to one or more first windings of the one or more transformers. In some aspects, control voltage applied to the voltage-variable capacitive elements to change the capacitance may be provided by supplying the one or more first windings with the voltage. The one or more first windings may include a center tap, and the control voltage may be applied to the center tap. It is to be noted that a transformer-based network inherently involves aspects associated with the inductance. The inductance properties of the transformer's coils (i.e. windings) enable the transfer of electrical energy between circuits, through the creation of varying magnetic fields in response to changing current in the primary winding, which in turn induces a voltage in the secondary winding.

It is to be noted herein, the term “DPA” (and accordingly SCDPA) used herein may refer to circuitry that is configured to receive an input digital signal and to provide an output signal at a desired power level for RF transmission in a DTX architecture by referencing to DPAs replacing analog PAs. Such circuitry may be referred to as a Digital to Power Converter (DPC) and may include a CDAC to convert the received input digital signal to the output signal, pointing to its aspects associated with conversion of DC energy to AC through controlled capacitive divider. CDACs may be referred to as capacitive RF digital to analog converters (RF-CDACs) or switched-capacitor RF-DACs.

Although the disclosure is designed to provide various aspects by providing examples involving transistors, such as p-type transistors and n-type transistors, it is to be noted that this terminology used herein may correspond to field effect transistors (FETs), in particular via p-channel metal oxide-semiconductors (PMOS) and n-channel metal oxide-semiconductors (NMOS) for the sake of brevity, the skilled person would recognize that aspects disclosed herein are related to any type of transistors of a first conductivity type (e.g. a PMOS) and a second conductivity type (e.g. NMOS) correspondingly a complementary metal oxide-semiconductors (CMOS), which may be realized through the use of other types of transistors (FET or non-FET), such as junction FETs (JFETs), metal-semiconductor FETs (MESFETs), a Fin FET (FinFET), high-electron-mobility transistors (HEMT), bipolar junction transistors (BJTs), insulated-gate bipolar transistors (IGBTs), etc.

As described in this disclosure, the SCDPA may operate with a modulated oscillator signal and accordingly the SCDPA may be configured to receive a digital input signal (e.g. modulated oscillator signal), which the digital signal input has a designated voltage swing. Within this context, the disclosure may use the term “signal swing”, “voltage swing”, or sometimes “swing”, which may refer to the variation in the voltage level of an electric signal over time. Correspondingly, the voltage level of an electric signal over time may refer to a variation between an upper voltage level and a lower voltage level. The upper voltage level and the lower voltage level may represent the highest voltage and the lowest voltage configured for the signal swing respectively. In other words, the voltage signal may refer to the peak-to-peak amplitude of the digital signal.

The apparatuses and methods of this disclosure may utilize or be related to radio communication technologies. While some examples may refer to specific radio communication technologies, the examples provided herein may be similarly applied to various other radio communication technologies, both existing and not yet formulated, particularly in cases where such radio communication technologies share similar features as disclosed regarding the following examples. Various exemplary radio communication technologies that the apparatuses and methods described herein may utilize include, but are not limited to: a Global System for Mobile Communications (“GSM”) radio communication technology, a General Packet Radio Service (“GPRS”) radio communication technology, an Enhanced Data Rates for GSM Evolution (“EDGE”) radio communication technology, and/or a Third Generation Partnership Project (“3GPP”) radio communication technology, for example Universal Mobile Telecommunications System (“UMTS”), Freedom of Multimedia Access (“FOMA”), 3GPP Long Term Evolution (“LTE”), 3GPP Long Term Evolution Advanced (“LTE Advanced”), Code division multiple access 2000 (“CDMA2000”), Cellular Digital Packet Data (“CDPD”), Mobitex, Third Generation (3G), Circuit Switched Data (“CSD”), High-Speed Circuit-Switched Data (“HSCSD”), Universal Mobile Telecommunications System (“Third Generation”) (“UMTS (3G)”), Wideband Code Division Multiple Access (Universal Mobile Telecommunications System) (“W-CDMA (UMTS)”), High Speed Packet Access (“HSPA”), High-Speed Downlink Packet Access (“HSDPA”), High-Speed Uplink Packet Access (“HSUPA”), High Speed Packet Access Plus (“HSPA+”), Universal Mobile Telecommunications System-Time-Division Duplex (“UMTS-TDD”), Time Division-Code Division Multiple Access (“TD-CDMA”), Time Division-Synchronous Code Division Multiple Access (“TD-CDMA”), 3rd Generation Partnership Project Release 8 (Pre-4th Generation) (“3GPP Rel. 8 (Pre-4G)”), 3GPP Rel. 9 (3rd Generation Partnership Project Release 9), 3GPP Rel. 10 (3rd Generation Partnership Project Release 10). 3GPP Rel. 11 (3rd Generation Partnership Project Release 11), 3GPP Rel. 12 (3rd Generation Partnership Project Release 12), 3GPP Rel. 13 (3rd Generation Partnership Project Release 13), 3GPP Rel. 14 (3rd Generation Partnership Project Release 14), 3GPP Rel. 15 (3rd Generation Partnership Project Release 15), 3GPP Rel. 16 (3rd Generation Partnership Project Release 16), 3GPP Rel. 17 (3rd Generation Partnership Project Release 17), 3GPP Rel. 18 (3rd Generation Partnership Project Release 18), 3GPP 5G, 3GPP LTE Extra, LTE-Advanced Pro, LTE Licensed-Assisted Access (“LAA”), MuLTEfire, UMTS Terrestrial Radio Access (“UTRA”), Evolved UMTS Terrestrial Radio Access (“E-UTRA”), Long Term Evolution Advanced (4th Generation) (“LTE Advanced (4G)”), cdmaOne (“2G”), Code division multiple access 2000 (Third generation) (“CDMA2000 (3G)”), Evolution-Data Optimized or Evolution-Data Only (“EV-DO”), Advanced Mobile Phone System (1st Generation) (“AMPS (1G)”), Total Access Communication arrangement/Extended Total Access Communication arrangement (“TACS/ETACS”), Digital AMPS (2nd Generation) (“D-AMPS (2G)”), Push-to-talk (“PTT”), Mobile Telephone System (“MTS”), Improved Mobile Telephone System (“IMTS”), Advanced Mobile Telephone System (“AMTS”), OLT (Norwegian for Offentlig Landmobil Telefoni, Public Land Mobile Telephony), MTD (Swedish abbreviation for Mobiltelefonisystem D, or Mobile telephony system D), Public Automated Land Mobile (“Autotel/PALM”), ARP (Finnish for Autoradiopuhelin, “car radio phone”), NMT (Nordic Mobile Telephony), High capacity version of NTT (Nippon Telegraph and Telephone) (“Hicap”), Cellular Digital Packet Data (“CDPD”), Mobitex, DataTAC, Integrated Digital Enhanced Network (“iDEN”), Personal Digital Cellular (“PDC”), Circuit Switched Data (“CSD”), Personal Handy-phone System (“PHS”), Wideband Integrated Digital Enhanced Network (“WiDEN”), iBurst, Unlicensed Mobile Access (“UMA”), also referred to as also referred to as 3GPP Generic Access Network, or GAN standard), Zigbee, Bluetooth®, Wireless Gigabit Alliance (“WiGig”) standard, mmWave standards in general (wireless systems operating at 10-300 GHz and above such as WiGig, IEEE 802.11ad, IEEE 802.11ay, etc.), technologies operating above 300 GHz and THz bands, (3GPP/LTE based or IEEE 802.11p and other) Vehicle-to-Vehicle (“V2V”) and Vehicle-to-X (“V2X”) and Vehicle-to-Infrastructure (“V2I”) and Infrastructure-to-Vehicle (“I2V”) communication technologies, 3GPP cellular V2X, DSRC (Dedicated Short Range Communications) communication arrangements such as Intelligent-Transport-Systems, and other existing, developing, or future radio communication technologies.

The apparatuses and methods described herein may use such radio communication technologies according to various spectrum management schemes, including, but not limited to, dedicated licensed spectrum, unlicensed spectrum, (licensed) shared spectrum (such as LSA=Licensed Shared Access in 2.3-2.4 GHZ. 3.4-3.6 GHZ, 3.6-3.8 GHz and further frequencies and SAS=Spectrum Access System in 3.55-3.7 GHZ and further frequencies), and may use various spectrum bands including, but not limited to, IMT (International Mobile Telecommunications) spectrum (including 450-470 MHZ, 790-960 MHZ, 1710-2025 MHz, 2110-2200 MHz, 2300-2400 MHZ, 2500-2690 MHZ, 698-790 MHZ, 610-790 MHZ, 3400-3600 MHZ, etc., where some bands may be limited to specific region(s) and/or countries), IMT-advanced spectrum, IMT-2020 spectrum (expected to include 3600-3800 MHZ, 3.5 GHZ bands, 700 MHz bands, bands within the 24.25-86 GHz range, etc.), spectrum made available under FCC's “Spectrum Frontier” 5G initiative (including 27.5-28.35 GHZ, 29.1-29.25 GHZ, 31-31.3 GHZ, 37-38.6 GHZ, 38.6-40 GHZ, 42-42.5 GHZ, 57-64 GHZ, 64-71 GHZ. 71-76 GHz. 81-86 GHZ and 92-94 GHZ, etc.), the ITS (Intelligent Transport Systems) band of 5.9 GHZ (typically 5.85-5.925 GHZ) and 63-64 GHZ, bands currently allocated to WiGig such as WiGig Band 1 (57.24-59.40 GHZ), WiGig Band 2 (59.40-61.56 GHZ) and WiGig Band 3 (61.56-63.72 GHZ) and WiGig Band 4 (63.72-65.88 GHZ), the 70.2 GHZ-71 GHz band, any band between 65.88 GHZ and 71 GHZ, bands currently allocated to automotive radar applications such as 76-81 GHZ, and future bands including 94-300 GHZ and above. Furthermore, the apparatuses and methods described herein can also employ radio communication technologies on a secondary basis on bands such as the TV White Space bands (typically below 790 MHZ) where e.g. the 400 MHZ and 700 MHz bands are prospective candidates. Besides cellular applications, specific applications for vertical markets may be addressed such as PMSE (Program Making and Special Events), medical, health, surgery, automotive, low-latency, drones, etc. applications. Furthermore, the apparatuses and methods described herein may also use radio communication technologies with a hierarchical application, such as by introducing a hierarchical prioritization of usage for different types of users (e.g., low/medium/high priority, etc.), based on a prioritized access to the spectrum e.g., with highest priority to tier-1 users, followed by tier-2, then tier-3, etc. users, etc.

The apparatuses and methods described herein can also use radio communication technologies with different Single Carrier or OFDM flavors (CP-OFDM, SC-FDMA, SC-OFDM, filter bank-based multicarrier (FBMC), OFDMA, etc.) and e.g. 3GPP NR (New Radio), which can include allocating the OFDM carrier data bit vectors to the corresponding symbol resources.

For purposes of this disclosure, radio communication technologies may be classified as one of a Short Range radio communication technology or Cellular Wide Area radio communication technology. Short Range radio communication technologies may include Bluetooth, WLAN (e.g., according to any IEEE 802.11 standard), and other similar radio communication technologies. Cellular Wide Area radio communication technologies may include Global System for Mobile Communications (“GSM”), Code Division Multiple Access 2000 (“CDMA2000”), Universal Mobile Telecommunications System (“UMTS”), Long Term Evolution (“LTE”), General Packet Radio Service (“GPRS”), Evolution-Data Optimized (“EV-DO”), Enhanced Data Rates for GSM Evolution (“EDGE”), High Speed Packet Access (HSPA; including High Speed Downlink Packet Access (“HSDPA”), High Speed Uplink Packet Access (“HSUPA”), HSDPA Plus (“HSDPA+”), and HSUPA Plus (“HSUPA+”)), Worldwide Interoperability for Microwave Access (“WiMax”) (e.g., according to an IEEE 802.16 radio communication standard, e.g., WiMax fixed or WiMax mobile), etc., and other similar radio communication technologies. Cellular Wide Area radio communication technologies also include “small cells” of such technologies, such as microcells, femtocells, and picocells. Cellular Wide Area radio communication technologies may be generally referred to herein as “cellular” communication technologies.

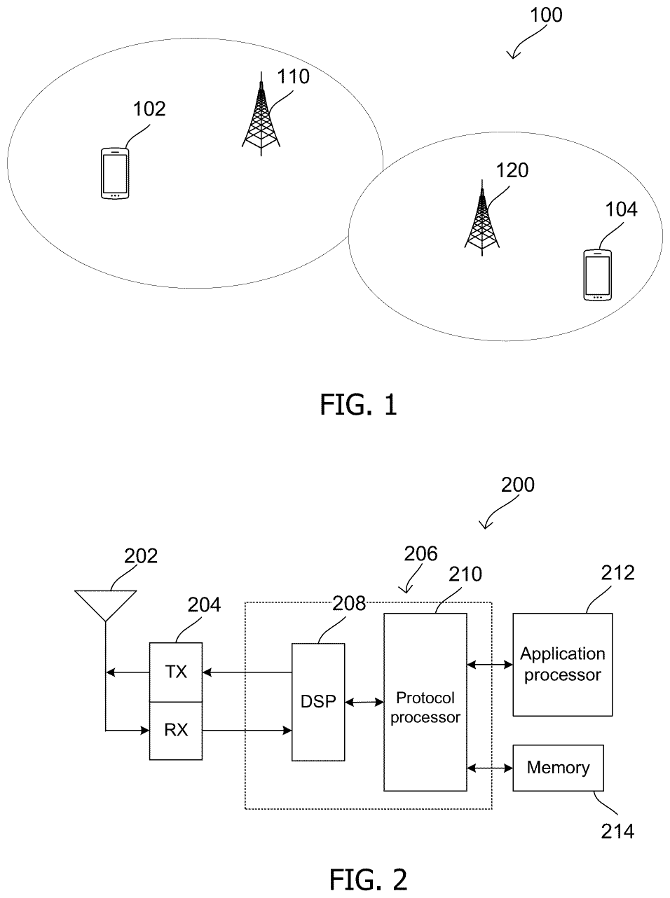

FIGS. 1 and 2 depict a general network and device architecture for wireless communications. In particular, FIG. 1 shows exemplary radio communication network 100 according to some aspects, which may include terminal devices 102 and 104 and network access nodes 110 and 120. Radio communication network 100 may communicate with terminal devices 102 and 104 via network access nodes 110 and 120 over a radio access network. Although certain examples described herein may refer to a particular radio access network context (e.g., LTE, UMTS, GSM, other 3rd Generation Partnership Project (3GPP) networks, WLAN/WiFi, Bluetooth, 5G NR, mmWave, etc.), these examples are demonstrative and may therefore be readily applied to any other type or configuration of radio access network. The number of network access nodes and terminal devices in radio communication network 100 is exemplary and is scalable to any amount.

In an exemplary cellular context, network access nodes 110 and 120 may be base stations (e.g., cNodeBs, NodeBs, Base Transceiver Stations (BTSs), gNodeBs, or any other type of base station), while terminal devices 102 and 104 may be cellular terminal devices (e.g., Mobile Stations (MSs), User Equipments (UEs), or any type of cellular terminal device). Network access nodes 110 and 120 may therefore interface (e.g., via backhaul interfaces) with a cellular core network such as an Evolved Packet Core (EPC, for LTE), Core Network (CN, for UMTS), or other cellular core networks, which may also be considered part of radio communication network 100. The cellular core network may interface with one or more external data networks. In an exemplary short-range context, network access node 110 and 120 may be access points (APs, e.g., WLAN or WiFi APs), while terminal device 102 and 104 may be short range terminal devices (e.g., stations (STAs)). Network access nodes 110 and 120 may interface (e.g., via an internal or external router) with one or more external data networks. Network access nodes 110 and 120 and terminal devices 102 and 104 may include one or multiple transmission/reception points (TRPs).

Network access nodes 110 and 120 (and, optionally, other network access nodes of radio communication network 100 not explicitly shown in FIG. 1) may accordingly provide a radio access network to terminal devices 102 and 104 (and, optionally, other terminal devices of radio communication network 100 not explicitly shown in FIG. 1). In an exemplary cellular context, the radio access network provided by network access nodes 110 and 120 may enable terminal devices 102 and 104 to wirelessly access the core network via radio communications. The core network may provide switching, routing, and transmission, for traffic data related to terminal devices 102 and 104, and may further provide access to various internal data networks (e.g., control nodes, routing nodes that transfer information between other terminal devices on radio communication network 100, etc.) and external data networks (e.g., data networks providing voice, text, multimedia (audio, video, image), and other Internet and application data). In an exemplary short-range context, the radio access network provided by network access nodes 110 and 120 may provide access to internal data networks (e.g., for transferring data between terminal devices connected to radio communication network 100) and external data networks (e.g., data networks providing voice, text, multimedia (audio, video, image), and other Internet and application data).

The radio access network and core network (if applicable, such as for a cellular context) of radio communication network 100 may be governed by communication protocols that can vary depending on the specifics of radio communication network 100. Such communication protocols may define the scheduling, formatting, and routing of both user and control data traffic through radio communication network 100, which includes the transmission and reception of such data through both the radio access and core network domains of radio communication network 100. Accordingly, terminal devices 102 and 104 and network access nodes 110 and 120 may follow the defined communication protocols to transmit and receive data over the radio access network domain of radio communication network 100, while the core network may follow the defined communication protocols to route data within and outside of the core network. Exemplary communication protocols include LTE, UMTS, GSM, WiMAX, Bluetooth, WiFi, mmWave, etc., any of which may be applicable to radio communication network 100.

FIG. 2 shows an exemplary internal configuration of a communication device according to various aspects provided in this disclosure. The communication device may include various aspects of network access nodes 110, 120 or various aspects of a terminal device 102 as well. The communication device 200 may include antenna system 202, radio frequency (RF) transceiver 204, baseband modem 206 (including digital signal processor 208 and protocol controller 210), application processor 212, and memory 214. Although not explicitly shown in FIG. 2, in some aspects communication device 200 may include one or more additional hardware and/or software components, such as processors/microprocessors, controllers/microcontrollers, other specialty or generic hardware/processors/circuits, peripheral device(s), memory, power supply, external device interface(s), subscriber identity module(s) (SIMs), user input/output devices (display(s), keypad(s), touchscreen(s), speaker(s), external button(s), camera(s), microphone(s), etc.), or other related components.

Communication device 200 may transmit and receive radio signals on one or more radio access networks. Baseband modem 206 may direct such communication functionality of communication device 200 according to the communication protocols associated with each radio access network, and may execute control over antenna system 202 and RF transceiver 204 to transmit and receive radio signals according to the formatting and scheduling parameters defined by each communication protocol. Although various practical designs may include separate communication components for each supported radio communication technology (e.g., a separate antenna, RF transceiver, digital signal processor, and controller), for purposes of conciseness the configuration of communication device 200 shown in FIG. 2 depicts only a single instance of such components.

Communication device 200 may transmit and receive wireless signals with antenna system 202. Antenna system 202 may be a single antenna or may include one or more antenna arrays that each include multiple antenna elements. For example, antenna system 202 may include an antenna array at the top of communication device 200 and a second antenna array at the bottom of communication device 200. In some aspects, antenna system 202 may additionally include analog antenna combination and/or beamforming circuitry.

In the receive (RX) path, RF transceiver 204 may receive analog radio frequency signals from antenna system 202 and perform analog and digital RF front-end processing on the analog radio frequency signals to produce digital baseband samples (e.g., In-Phase/Quadrature (IQ) samples) to provide to baseband modem 206. RF transceiver 204 may include analog and digital reception components including amplifiers (e.g., Low Noise Amplifiers (LNAs)), filters, RF demodulators (e.g., RF IQ demodulators)), and analog-to-digital converters (ADCs), which RF transceiver 204 may utilize to convert the received radio frequency signals to digital baseband samples. In the transmit (TX) path, RF transceiver 204 may receive digital baseband samples from baseband modem 206 and perform analog and digital RF front-end processing on the digital baseband samples to produce analog radio frequency signals to provide to antenna system 202 for wireless transmission. RF transceiver 204 may thus include analog and digital transmission components including amplifiers (e.g., Power Amplifiers (PAS), filters, RF modulators (e.g., RF IQ modulators), and digital-to-analog converters (DACs), which RF transceiver 204 may utilize to mix the digital baseband samples received from baseband modem 206 and produce the analog radio frequency signals for wireless transmission by antenna system 202. In some aspects baseband modem 206 may control the radio transmission and reception of RF transceiver 204, including specifying the transmit and receive radio frequencies for operation of RF transceiver 204. In some aspects, RF transceiver 204 may include a DTX architecture including a DPA (e.g. an SCDPA) as described herein.

As shown in FIG. 2, baseband modem 206 may include digital signal processor 208, which may perform physical layer (PHY, Layer 1) transmission and reception processing to, in the transmit path, prepare outgoing transmit data provided by protocol controller 210 for transmission via RF transceiver 204, and, in the receive path, prepare incoming received data provided by RF transceiver 204 for processing by protocol controller 210. Digital signal processor 208 may be configured to perform one or more of error detection, forward error correction encoding/decoding, channel coding and interleaving, channel modulation/demodulation, physical channel mapping, radio measurement and search, frequency and time synchronization, antenna diversity processing, power control and weighting, rate matching/de-matching, retransmission processing, interference cancelation, and any other physical layer processing functions. Digital signal processor 208 may be structurally realized as hardware components (e.g., as one or more digitally-configured hardware circuits or FPGAs), software-defined components (e.g., one or more processors configured to execute program code defining arithmetic, control, and I/O instructions (e.g., software and/or firmware) stored in a non-transitory computer-readable storage medium), or as a combination of hardware and software components. In some aspects, digital signal processor 208 may include one or more processors configured to retrieve and execute program code that defines control and processing logic for physical layer processing operations. In some aspects, digital signal processor 208 may execute processing functions with software via the execution of executable instructions. In some aspects, digital signal processor 208 may include one or more dedicated hardware circuits (e.g., ASICs, FPGAs, and other hardware) that are digitally configured to specific execute processing functions, where the one or more processors of digital signal processor 208 may offload certain processing tasks to these dedicated hardware circuits, which are known as hardware accelerators. Exemplary hardware accelerators can include Fast Fourier Transform (FFT) circuits and encoder/decoder circuits. In some aspects, the processor and hardware accelerator components of digital signal processor 208 may be realized as a coupled integrated circuit.

Communication device 200 may be configured to operate according to one or more radio communication technologies. Digital signal processor 208 may be responsible for lower-layer processing functions (e.g., Layer 1/PHY) of the radio communication technologies, while protocol controller 210 may be responsible for upper-layer protocol stack functions (e.g., Data Link Layer/Layer 2 and/or Network Layer/Layer 3). Protocol controller 210 may thus be responsible for controlling the radio communication components of communication device 200 (antenna system 202, RF transceiver 204, and digital signal processor 208) in accordance with the communication protocols of each supported radio communication technology, and accordingly may represent the Access Stratum and Non-Access Stratum (NAS) (also encompassing Layer 2 and Layer 3) of each supported radio communication technology. Protocol controller 210 may be structurally embodied as a protocol processor configured to execute protocol stack software (retrieved from a controller memory) and subsequently control the radio communication components of communication device 200 to transmit and receive communication signals in accordance with the corresponding protocol stack control logic defined in the protocol software. Protocol controller 210 may include one or more processors configured to retrieve and execute program code that defines the upper-layer protocol stack logic for one or more radio communication technologies, which can include Data Link Layer/Layer 2 and Network Layer/Layer 3 functions. Protocol controller 210 may be configured to perform both user-plane and control-plane functions to facilitate the transfer of application layer data to and from radio communication device 200 according to the specific protocols of the supported radio communication technology. User-plane functions can include header compression and encapsulation, security, error checking and correction, channel multiplexing, scheduling and priority, while control-plane functions may include setup and maintenance of radio bearers. The program code retrieved and executed by protocol controller 210 may include executable instructions that define the logic of such functions.

Communication device 200 may also include application processor 212 and memory 214. Application processor 212 may be a CPU, and may be configured to handle the layers above the protocol stack, including the transport and application layers. Application processor 212 may be configured to execute various applications and/or programs of communication device 200 at an application layer of communication device 200, such as an operating system (OS), a user interface (UI) for supporting user interaction with communication device 200, and/or various user applications. The application processor may interface with baseband modem 206 and act as a source (in the transmit path) and a sink (in the receive path) for user data, such as voice data, audio/video/image data, messaging data, application data, basic Internet/web access data, etc. In the transmit path, protocol controller 210 may therefore receive and process outgoing data provided by application processor 212 according to the layer-specific functions of the protocol stack, and provide the resulting data to digital signal processor 208. Digital signal processor 208 may then perform physical layer processing on the received data to produce digital baseband samples, which digital signal processor may provide to RF transceiver 204. RF transceiver 204 may then process the digital baseband samples to convert the digital baseband samples to analog RF signals, which RF transceiver 204 may wirelessly transmit via antenna system 202. In the receive path, RF transceiver 204 may receive analog RF signals from antenna system 202 and process the analog RF signals to obtain digital baseband samples. RF transceiver 204 may provide the digital baseband samples to digital signal processor 208, which may perform physical layer processing on the digital baseband samples. Digital signal processor 208 may then provide the resulting data to protocol controller 210, which may process the resulting data according to the layer-specific functions of the protocol stack and provide the resulting incoming data to application processor 212. Application processor 212 may then handle the incoming data at the application layer, which can include execution of one or more application programs with the data and/or presentation of the data to a user via a user interface.

Memory 214 may embody a memory component of communication device 200, such as a hard drive or another such permanent memory device. Although not explicitly depicted in FIG. 2, the various other components of communication device 200 shown in FIG. 2 may additionally each include integrated permanent and non-permanent memory components, such as for storing software program code, buffering data, etc.

In accordance with some radio communication networks, terminal devices 102 and 104 may execute mobility procedures to connect to, disconnect from, and switch between available network access nodes of the radio access network of radio communication network 100. As each network access node of radio communication network 100 may have a specific coverage area, terminal devices 102 and 104 may be configured to select and re-select \ available network access nodes in order to maintain a strong radio access connection with the radio access network of radio communication network 100. For example, terminal device 102 may establish a radio access connection with network access node 110 while terminal device 104 may establish a radio access connection with network access node 112. In the event that the current radio access connection degrades, terminal devices 102 or 104 may seek a new radio access connection with another network access node of radio communication network 100; for example, terminal device 104 may move from the coverage area of network access node 112 into the coverage area of network access node 110. As a result, the radio access connection with network access node 112 may degrade, which terminal device 104 may detect via radio measurements such as signal strength or signal quality measurements of network access node 112. Depending on the mobility procedures defined in the appropriate network protocols for radio communication network 100, terminal device 104 may seek a new radio access connection (which may be, for example, triggered at terminal device 104 or by the radio access network), such as by performing radio measurements on neighboring network access nodes to determine whether any neighboring network access nodes can provide a suitable radio access connection. As terminal device 104 may have moved into the coverage area of network access node 110, terminal device 104 may identify network access node 110 (which may be selected by terminal device 104 or selected by the radio access network) and transfer to a new radio access connection with network access node 110. Such mobility procedures, including radio measurements, cell selection/reselection, and handover are established in the various network protocols and may be employed by terminal devices and the radio access network in order to maintain strong radio access connections between each terminal device and the radio access network across any number of different radio access network scenarios.

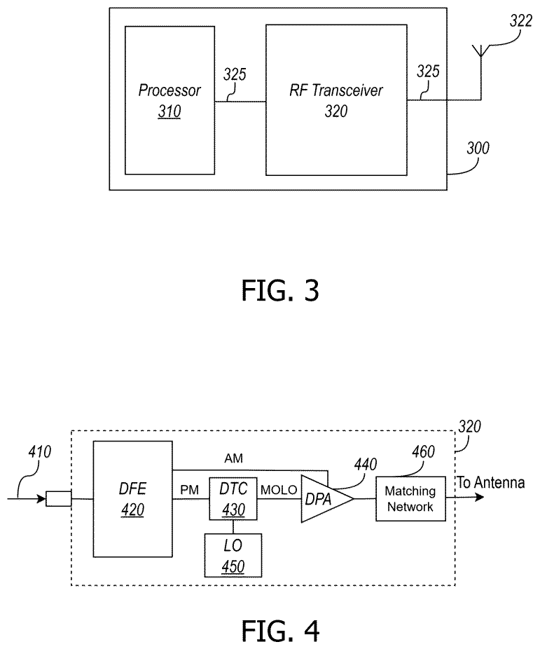

FIG. 3 shows an exemplary illustration of various communication elements of an apparatus for a wireless communication device (e.g. the communication device 200). The apparatus 300 may include processing circuitry 310 (e.g. the baseband modem 206, the application processor 212) that may direct and manage communication operations of the apparatus 300 according to one or more radio communication protocols, and may control transmission/reception of communication signals over at least one or more antenna 322 via an RF transceiver 320. The processing circuitry 310 may include an interface to the RF transceiver 320. The RF transceiver 320 may include at least one RF-chain to process the communication signals associated with the antenna 322 respectively. The apparatus 300 may include the antenna 322, or the apparatus 300 may include an antenna interface couplable to the antenna 322. It is to be noted that the apparatus 300 is depicted as being couplable to the antenna 322, but the apparatus 300 may be couplable to a plurality of antennas, and thereby the RF transceiver 320 may include a plurality of RF-chains, each RF-chain may process communication signals for a respective antenna. The apparatus 300 may transmit and receive radio communication signals with the antenna 322. The apparatus 300 may act as an RF transmitter (e.g. RF transmit circuit) to transmit radio communication signals and it may also act as an RF receiver (e.g. RF receive circuit) to receive radio communication signals.

The processing circuitry 310 may include, or may be implemented, partially or entirely, by circuit and/or logic, e.g., a processor including circuit and/or logic, a memory circuit and/or a logic, which may be configured to manage radio communication operations. The processing circuitry 310 may be configured to communicate with an external main processor (e.g. a host processor, a central processing unit (CPU), a system on chip (SoC)) of the wireless communication device including the apparatus 300 via a designated interface that is coupled to the main processor. In some examples, the processing circuitry 310 may be the main processor of the wireless communication device. The processing circuitry 310 may also access the main memory of the respective wireless communication device via the designated interface. The processing circuitry 310 may further include an interface to the RF transceiver 320.

The processing circuitry 310 may include a digital signal processor (e.g. the digital signal processor 208). The digital signal processor 208 may be configured to perform one or more of error detection, forward error correction encoding/decoding, channel coding, and interleaving, channel modulation/demodulation, physical channel mapping, radio measurement and search, frequency and time synchronization, antenna diversity processing, power control, and weighting, rate matching/de-matching, retransmission processing, interference cancelation, and any other physical layer processing functions.

The processing circuitry 310 may include a modem configured to process baseband signals received from/sent to the antenna 322 via a communication path 325 including a respective RF chain. In various examples, the interface to the RF transceiver 320 of the processing circuitry 310 may be configured to couple the processing circuitry 310 to the communication path 325. Accordingly, the processing circuitry 310 may include Media-Access Control (MAC) circuit and/or logic, Physical Layer (PHY) circuit and/or logic, baseband (BB) circuit and/or logic, a BB processor, a BB memory, Application Processor (AP) circuit and/or logic, an AP processor, an AP memory, and/or any other circuit and/or logic. By way of example, the processing circuitry 310 can perform baseband processing on the digital baseband signals to recover data included in wireless data transmissions.

The processing circuitry 310 may control and/or arbitrate transmit and/or receive functions of the apparatus 300, and perform one or more baseband processing functions (e.g., media access control (MAC), encoding/decoding, modulation/demodulation, data symbol mapping, error correction, etc.). The processing circuitry 310 may be configured to provide control functions to the RF transceiver 320 (e.g. to the RF-chain to control and/or arbitrate transmitting and/or receiving radio communication signals). In aspects, functions of processing circuitry 310 can be implemented in software and/or firmware executing on one or more suitable programmable processors, and may be implemented, for example, in a field programmable gate array (FPGA), application specific integrated circuit (ASIC), etc. In various examples, the interface to the RF transceiver 320 of the processing circuitry 310 may be configured to couple processing circuitry to the RF transceiver to provide communication in-between.

The RF transceiver 320 may provide RF processing of communication signals conveyed via a communication path within a respective RF chain to transmit radio communication signals via a respective antenna based on signals (e.g. baseband communication signals, digital signals) received from the processing circuitry 310 over the communication path. The RF transceiver 320 may provide RF processing of communication signals conveyed via the communication path 325 to receive radio communication signals via the antenna 322 and provide signals to the processing circuitry 310 over the communication path 325. The processing circuitry 310 may be configured to control operations of the RF transceiver 320. The RF transceiver 320 may include a receive path to provide RF processing to receive radio communication signals received from the antenna 322, and a transmit path to provide RF processing to transmit radio communication signals transmitted via the antenna 322.

In a receive (RX) path, The RF transceiver 320 may receive analog radio frequency signals from the antenna 322 via the communication paths 325 and perform analog and digital RF front-end processing on the analog radio frequency signals to produce digital baseband samples (e.g., In-Phase/Quadrature (IQ) samples) to provide to the processing circuitry 310. In various examples, RF transceiver 320 may include two RF-chains per antenna element, each RF-chain may be designated for a particular polarization. The RF transceiver 320 may include analog and digital reception components including amplifiers (e.g., Low Noise Amplifiers (LNAs)), filters, RF demodulators (e.g., RF IQ demodulators)), and analog-to-digital converters (ADCs), which RF transceiver 320 may utilize to convert the received radio frequency signals to digital baseband samples.

In a transmit (TX) path, the RF transceiver 320 may receive digital baseband samples from processing circuitry 310 and perform analog and digital RF front-end processing on the digital baseband samples to produce analog radio frequency signals to be provided to the antenna 322 via the communication paths 325 for radio transmission. The RF transceiver 320 may thus include analog and digital transmission components including amplifiers (e.g., Power Amplifiers (PAS), filters, RF modulators (e.g., RF IQ modulators), and digital-to-analog converters (DACs), which the RF transceiver 320 may utilize to mix the digital baseband samples received from processing circuitry 310 and produce respective analog radio frequency signals for radio transmission by the antenna 322. In some aspects, the processing circuitry 310 may control the radio transmission and reception of the RF transceiver 320, including specifying the transmit and receive radio frequencies for the operation of the RF transceiver 320. In some examples, the RF transceiver 320 may include a DTX architecture including DPA described herein. In some examples, operations associated with the digital front-end may be provided by the processing circuitry 310 as well, or in other words, the processing circuitry 310 may include the digital front-end.

FIG. 4 shows an exemplary illustration of a transmit path of an RF transceiver. The RF transceiver 320, of which the transmit path illustrated herein, may be configured for a digital polar TX. The RF transceiver 320 may be couplable to processing circuitry (e.g. the processing circuitry 310, a modem) over an interface. The interface may include a communication path designated to carry communication signals 410 between the processing circuitry and an antenna. In some examples, the interface may include a further circuit path to provide communication between the RF transceiver 320 and the processing circuitry for control of the operations. The RF transceiver 320 may further include further components and or circuits, such as further filter circuits, synthesizer circuits, etc. that are not depicted here. The RF transceiver 320 may include various circuits and components deployed on the respective transmission path.

The RF transceiver 320 may include a digital front end (DFE) 420. The DFE 420 may receive the communication signals 410 via the interface coupling the processing circuitry to the DFE 420. The DFE 420 may include a DFE processing circuitry and further components. The DFE may 420 be configured to convert the communication signals 410 (e.g. in-phase/quadrature (IQ) signals) into a polar signal including an amplitude modulation (AM) signal (e.g. amplitude control codes) and a phase modulation (PM) signal (e.g. phase control codes).

In more detail, the DFE 420 may be configured to convert baseband data to AM control codes and PM control codes to be used by the DPA 440 and the DTC 430 respectively to generate RF communication signal to be transmitted from the transmit path. Exemplarily, the DFE 420 may include a modem for modulation/demodulation of signals (e.g. to output IQ data) and a coordinate rotation digital computer (CORDIC) unit configured to perform a series of rotations of the IQ data to calculate the phase and amplitude of the signal. The DFE 420 may accordingly provide the phase control code and the amplitude control code representative of calculated phase and amplitude respectively.

The RF transceiver 320 may further include a digital to time converter (DTC) 430 circuit. The DTC 430 may be coupled to the DFE 420. The DTC 430 may receive the phase modulation signal. The DTC 430 may be further coupled to a local oscillator (LO) 450. The DTC 430 may adjust polar modulation parameters based on the PM signal (e.g. phase control codes) that the DFE 420 provides to generate a modulated signal. By adjusting the polar modulation parameters based on the PM signal, the DTC 430 may output a modulated local oscillator (MOLO) signal.

The RF transceiver 320 may further include a digital power amplifier (DPA) 440. The DPA 440 may receive the AM signal (e.g. amplitude control codes) setting desired power of the output of the DPA 440. DPA 440 may further receive the MOLO signal (i.e. output of the DTC 430) and provide an output RF signal based on the received MOLO signal and received AM signal. The DPA 440 may include a DPC, or a CDAC as described herein.

The DPA 440 may be coupled to a matching network 460 for impedance matching within the transmission chain and for filtering out unwanted frequencies and harmonics. The matching network 460 may exemplarily be a transformer based matching network, and the output terminal of the DPA 440 may be coupled to a first winding of a transformer of the transformer based matching network. A second winding of the transformer may be couplable to an antenna port and/or an antenna for transmission of RF communication signal.

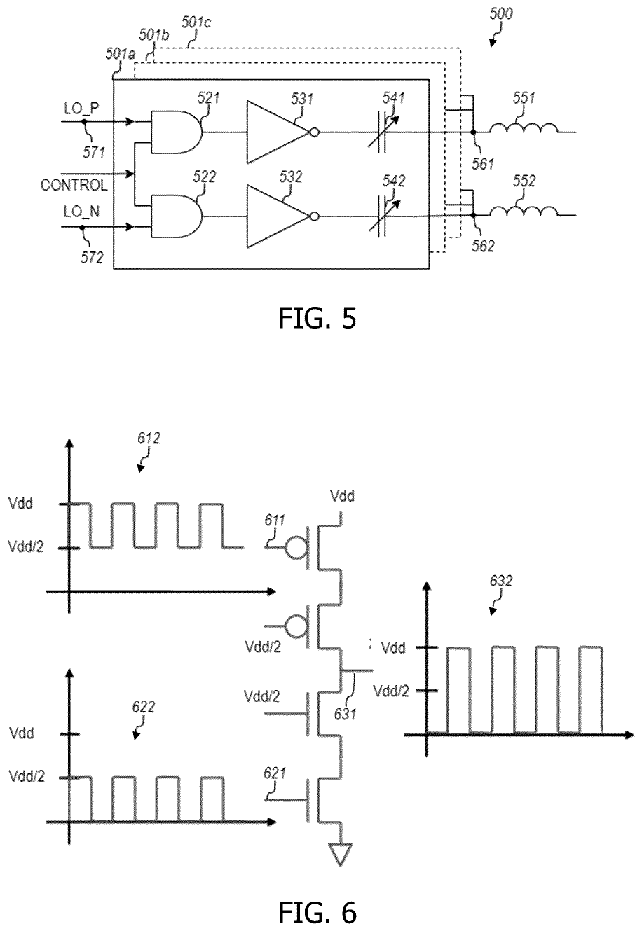

FIG. 5 schematically shows an example of an SCDPA. A communication device (e.g. the communication device 200, the apparatus 300, the RF transceiver 320) may include the SCDPA 500. The SCDPA 500 is depicted to include multiple SCDPA cells 501a-c. e.g. an array of SCDPA cells. The SCDPA cells may also be referred to as unit cells of the SCDPA. The illustrative example provided herein includes three SCDPA cells, 501a, 501b, and 501c. The number of SCDPA cells within the SCDPA 500 may vary depending on desired configuration parameters associated with the SCDPA 500 and desired characteristics of output signals of the SCDPA 500. Typically, the number of cells of an SCDPA may be 64, 128, 256, etc. Each SCDPA cell 501a-c may include a capacitive element (e.g. a capacitor) 541, 542 and may provide an output signal (e.g. a cell output signal) through discharging of the capacitive element 541, 542.

Each SCDPA cell 501a-c may include at least one logic component configured to cause the SCDPA cell 501a-c to operate in an active mode or in an inactive mode based on the received control signal. This illustrative example includes a first logic component as a first AND gate and a second logic component as a second AND gate. Particularly, each SCDPA cell 501a-c may include at least one driver (i.e. driver component or driver circuitry) configured to drive the capacitive element 541, 542 of the SCDPA cell 501a-c based on a received digital input signal.

The amplitude of output of the SCDPA 500 may be regulated by selecting a specific number of capacitive elements from the total array for switching. In other words, the SCDPA 500 may provide an output signal by selectively activating (or deactivating) the SCDPA cells 501a-c. For this purpose, a controller connected to the SCDPA may selectively activate or deactivate the SCDPA cells 501a-c. The controller may determine which SCDPA cells 501a-c are to be activated based on the amplitude control codes.

In an embodiment, the controller may determine which SCDPA cells 501a-c are to be activated adaptively, exemplarily based on output of the SCDPA 500, or a signal received from a separate control circuit. The adaptive determination may be based on power output requirements, criteria, or constraints. The signal may be representative of increasing the output power of the SCDPA or decreasing the output power of the SCDPA based on power output requirements, criteria, or constraints.

Accordingly, each SCDPA cell 501a-c may be configured to operate in an active mode in which the SCDPA cell 501 may provide an output signal based on a received input signal, and in an inactive mode in which the SCDPA cell 501a-c does not provide an output signal based on the received input signal. Each SCDPA cell 501a-c may include a logic component used to control whether the SCDPA cell 501a-c is in active or inactive mode based on the received control signal. The output signal is provided by charging or discharging of the capacitive elements 541, 542.

The driver may cause the capacitive element 541, 542 to be charged or discharged based on received digital input signals. In particular, within the context provided for the operation modes, the driver may be configured to cause the capacitive element 541, 542 to be charged or discharged in the active mode. In an inactive mode, exemplarily, the driver may not receive the digital input signals or the driver may not provide a signal to the capacitive element 541, 542, or may provide signal that is not based on the received input signals. Exemplarily, one or more logic components as described in this description may provide a low signal (or a high signal) that is constant for multiple clock cycles within the period of time of the inactive mode. A further switch may be introduced to cut off the signal provided to the driver.

In this illustrative example, the SCDPA cells 501a-c are configured to receive a first digital input signal (LO_P) from a first input terminal 571, a second digital input signal (LO_N) from a second input terminal 572. Each SCDPA cell 501a-c may be coupled to the first input terminal 571 and the second input terminal 572. Furthermore, each SCDPA cell 501a-c may be configured to receive a control signal. The control signal may be specific for each SCDPA cell 501a-c. The LO_P signal and the LO_N signal may be common for all the SCDPA cells 501a-c. The LO_P signal and the LO_N signals are digital signals, exemplarily being modulated LO signals provided by a DTC. Each SCDPA cell 501a-c may be considered as a circuit to receive a digital signal to be converted into an analog signal (e.g. a signal contributing to output signal as an output of SCDPA (e.g. output power signal of DPC)), the digital signal to be converted into the analog signal may be the LO_P signal and/or the LO_N signal. The analog signal may be output of the SCDPA (e.g. a power signal).

Exemplarily, the controller may determine a number of SCDPA cells 501a-c to be activated from the SCDPA cells 501a-c, the number is being n as an integer between 0 and the N total number of SCDPA cells 501a-c of the SCDPA 500, and provide first control signals (i.e. 1 in this illustrative example) to n number of SCDPA cells 501a-c to activate selected n number of SCDPA cells 501a-c. The controller may further provide second control signals (i.e. 0 in this illustrative example) to the remaining SCDPA cells 50a-c (number N-n) to operate them in an inactive mode.

In this illustrative example, the first AND gate 521 and the second AND gate 522 are provided as logic components used to cause the SCDPA cell 501a-c cell to operate in the active mode or in the inactive mode. The first AND gate 521 may receive the LO_P signal and the control signal, and the second AND gate 522 may receive the LO_N signal and the control signal. The outputs of the two AND gates 521, 522 are connected to separate inverters 531, 532, namely, a first inverter 531 and a second inverter 532. Each inverter 531, 532 is connected to a separate capacitive element (a first capacitive element and a second capacitive element respectively) 541, 542.

As depicted herein, the first capacitive elements 541 of the SCDPA cells 501a-c may be coupled to a first output terminal 561 that is common for the all SCDPA cells 501a-c, to provide a first output of the SCDPA (a first SCDPA output). The second capacitive elements 542 of the SCDPA cells 501a-c may be coupled to a second output terminal 562 that is common for the all SCDPA cells 501a-c, to provide a second output of the SCDPA (a second SCDPA output). In other words, the first capacitive elements 541 of each SCDPA cell 501a-c may be coupled to the first inverters 531 respectively at one end, and to the first output terminal 561 at the other end to discharge towards the first output terminal 561. Similarly, the second capacitive elements 542 of each SCDPA cell 501a-c may be coupled to the second inverters 532 respectively at one end, and to the second output terminal 562 at the other end to discharge towards the second output terminal 562.

It is to be noted that each illustrated SCDPA cell 501a-c is depicted in a differential configuration, in which each SCDPA cell 501a-c includes a first signal path including the signal path used to conduct the LO_P signal and a second signal path including the signal path used to conduct the LO_N signal. In other words, the first signal path may include the first input terminal 571, the first AND gate 521 to receive the LO_P signal, the first inverter 531 connected to the output of the first AND gate 521, and the first capacitive element 541 connected to output of the first inverter 531, and the first output terminal 561. The second signal path may include the second input terminal 572, the second AND gate 522 to receive the LO_N signal, the second inverter 532 connected to the output of the second AND gate 522, and the second capacitive element 542 connected to output of the second inverter 532, and the second output terminal 562.

The output terminals of the SCDPA, i.e. the first output terminal 561 and the second output terminal 562, may be coupled to a transformer-based matching network including at least one transformer. In this illustrative example, the first output terminal 561 is depicted to be connected to a first primary winding 551 of a transformer of the transformer-based matching network, and the second output terminal 562 is depicted to be connected to a second primary winding 552 of the transformer to combine the two outputs of the SCDPA in differential configuration to the secondary winding of the transformer. In accordance with various aspects provided in this disclosure, the first primary winding and the second primary winding may be implemented by a single primary winding with a center tap provided on the single primary winding.

Transformers described in this description may be any type of transformers that are suitable for DTX architecture. Such a transformer may include, in particular, a balun (i.e. balun transformer), an RF transformer optimized for use at radio frequencies, and/or a transmission line transformer. In some embodiments, the transformer may be a more complex structure, such as a capacitive voltage transformer.

In the first signal path, the control signal setting the active mode, may cause the first AND gate 521 to provide the received LO_P signal from its output to the first inverter 531. The first inverter 531, as a driver of the first signal path, may cause the first capacitive element 541 to be charged or discharged. In operation, when the LO_P signal is low, the first AND gate 521 may allow the LO_P signal to pass through the first inverter 531, and the first capacitive element 541 connected to the output of the inverter 531 charges. When the LO_P signal is high, the LO_P signal passes through the first inverter 531, and the first capacitive element 541 connected to the output of the first inverter 531 discharges.

In the second signal path, the control signal setting the active mode, may cause the second AND gate 522 to provide the received LO_N signal from its output to the second inverter 532. The second inverter 532, as a driver of the second signal path, may cause the second capacitive element 542 to be charged or discharged. In operation, when the LO_N signal is low, the second AND gate 522 may allow the LO_N signal to pass through the second inverter 532, and the second capacitive element 542 connected to the output of the second inverter 532 charges. When the LO_N signal is high, the LO_N signal passes through the second inverter 532, and the second capacitive element 542 connected to the output of the second inverter 532 discharges.

In some aspects, it is to be noted that the LO_P signal and the LO_N signal may be signals that are in phase, each varying between an upper voltage level and a lower voltage level with a voltage swing that is equal to another. The upper voltage levels and the lower voltage levels of the LO_P signal and the LO_N signal respectively may be different upper voltage levels and different lower voltage levels, but the voltage swing (i.e. difference between the upper voltage level and the lower voltage level) may be the same, causing the first inverter 531 and the second inverter 532 to toggle between a Vss voltage (i.e. output voltage level of the respective inverter is at a lower voltage level) and a Vdd voltage (i.e. output voltage level of the respective inverter is at a higher voltage level).

In implementation, SCDPA cells may be structured in various configurations, some of which may be in a different structure than what is illustrated in FIG. 5. The skilled person would know how to reflect the teachings provided herein, some including aspects described functionally, to different structures. Particularly, it is to be noted that the illustrated SCDPA 500 is provided in the differential configuration as an effective approach, but a single-ended approach including only one signal path per SCDPA cell may also be considered. In that particular example, the SCDPA 500 may include SCDPA cells that include only one signal path, rather the first signal path and the second signal path provided for the SCDPA cells 501a-c.

In theory, one of the considerations of a DPA design may include the quality factor as a measure to characterize bandwidth of the DPA relative to a center frequency, which the quality factor (QL) may be representative of the losses. In particular, in an SCDPA such as the SCDPA, QL may represent how effective capacitive elements are at storing energy compared to the amount of energy it dissipates. Theoretically, QL of a capacitive element may calculated using the following formula: Q=1/(2πfCR), where f is the frequency, C is the capacitance, and R is the equivalent series resistance.

In accordance with various aspects provided in this disclosure, the capacitive elements 541, 542 may be, or may include, variable capacitive elements. By varying the capacitance of the variable capacitive elements 541, 542 of the SCDPA according to the frequency band in which RF communication signal including SCDPA output signal is to be transmitted, desired characteristics for multi-band RF operations may be obtained. Exemplarily, the capacitance of the variable capacitive elements 541, 542 may be set to a first capacitance value for transmission of the RF communication signals in a first frequency band and the capacitance of the variable capacitive elements 541, 542 may be set to a second capacitance value for transmission of the RF communication signals in a second frequency band.

In various aspects, the variable capacitive elements 541, 542 may be voltage-variable capacitive elements (i.e. voltage-controlled) to vary the capacitance of the variable capacitive elements 541, 542 based on an electrical voltage applied to the variable capacitive elements. In some examples, the voltage-variable capacitive elements 541, 542 may be varactors (or varicap) to vary the capacitance with the voltage the varactor is subjected to. A varactor, in a reverse-biased operation, is configured to form an insulating depletion region between its p-type and n-type semiconductors, and the applied reverse-bias voltage may determine the width of this depletion region, and thereby the capacitance of the varactor. When the applied reverse voltage is increased, the depletion region width also increases, reducing the capacitance. Conversely, if the applied reverse voltage is decreased, the depletion region width decreases, thereby increasing the capacitance.

The voltage-variable capacitive elements 541, 542 (e.g. voltage-controlled capacitor, voltage-tunable capacitor, voltage-adjustable capacitive element, varactor such as a metal oxide semiconductor (MOS) varactor) may be configured for a voltage-controlled operation to change the capacitance. A voltage applied to a terminal coupled to the voltage-variable capacitive elements 541, 542 may cause the change of the capacitance of the voltage-variable capacitive elements 541, 542, and respectively the capacitance of the SCDPA cell 501a-c that the voltage-variable capacitive elements 541, 542 included by. In various aspects, the SCDPA may be coupled to a voltage supply circuit and a controller to control the capacitance of the voltage-variable capacitive elements 541, 542.

In various aspects, the voltage-variable capacitive elements 541, 542 may be MOS varactors (MOS varicaps, MOSCVs). A MOS varactor is a three-layer structure, typically including a metal gate, a thin oxide layer (the dielectric), and a semiconductor substrate. The capacitance of the MOS varactor may change based on the voltage applied to the gate of the MOS varactor.

There are various types of MOS varactors in different structures with p-n type elements. In some examples, drain, source, and bulk of a MOS is coupled to each other forming a first terminal of the MOS varactor, while the gate of the MOS becomes a second terminal of the MOS varactor. In some examples, drain and source of the MOS may be connected to each other forming a first terminal of the MOS varactor, while the gate of the MOS becomes a second terminal of the MOS varactor, and the bulk as a third terminal may be connected to the highest voltage within the circuit. In some examples, the MOS is configured to operate in an accumulation mode in a structure in which the drain and source connected to each other. Aspects of a realization of a particular MOS structure will not be discussed in this disclosure.

In general, voltage applied to a terminal of a MOS varactor may influence the electric field in the semiconductor substrate, resulting in a modification in the amount of charge carriers (i.e. electrons or holes) in the region under the thin oxide layer, which the region may also be referred to as the inversion layer. Exemplarily, when a first voltage (e.g. positive) is applied to the gate (for a MOS varactor with an NMOS structure), the electrons become attracted from the substrate towards the oxide layer, forming an inversion layer. When the gate voltage is increased, more electrons may be drawn to the inversion layer, increasing the density of the inversion layer and, thereby increasing the capacitance. Conversely, when the gate voltage is decreased, the density of the inversion layer is also decreased, thereby reducing the capacitance. In some examples, variation of the voltage applied to the first terminal (e.g. terminal coupled to the drain and the source, and possibly the bulk) in the above-mentioned MOS varactor examples may result in change of the capacitance of the MOS varactor.

In accordance with this illustrative example, a voltage to control capacitance of the voltage-controlled capacitance elements 541, 542 may be applied from the output terminals to the voltage-controlled capacitance elements 541, 542. Illustratively, a controllable voltage supply circuit may be coupled to the first output terminal 561 that is connected to the first voltage-controller capacitance elements 541 of the SCDPA cells 501a-c. The controllable voltage supply circuit may also be coupled to the second output terminal 562 that is connected to the second voltage-controller capacitance elements 541 of the SCDPA cells 501a-c. The controllable voltage supply circuit may apply different voltage levels to the first output terminal 561 and the second output terminal 562 to control the capacitance of the SCDPA cells 501a-c.

It is to be noted herein, that a maximum operating voltage of a transistor may also include maximum voltage levels that are applicable to any two terminals of a transistor that may damage operation of the transistor. VDmax representation provided in this disclosure as an exemplary transistor limitation in accordance with various aspects, but aspects provided herein may correspond to further voltage level limitations. In other words, it may further refer to maximum drain-source voltage, maximum drain-gate voltage, or maximum gate-source voltage of a FET, and similar voltages between terminals of other types of transistors.

FIG. 6 illustrates an example of a driver of an SCDPA with 2-level transistor stacking to drive capacitors of an SCDPA cell. The driver illustrated herein includes four transistors connected in series (i.e. from their drain-source terminals respectively). The four transistors including two p-type transistors as transistors of a first conductivity type, and two n-type transistors as transistors of a second conductivity type. Exemplarily, the transistors of the first conductivity type are a first p-type transistor and a second p-type transistor connected to the first p-type transistor. The transistors of the second conductivity type are a first n-type transistor and a second n-type transistor connected to the first n-type transistor. The first p-type transistor includes a control terminal 611 (gate terminal) configured to receive a first input signal. The first n-type transistor includes a control terminal 621 configured to receive a second input signal.

Assuming that the transistors have the same VDmax, the first digital input signal 612 may vary within a voltage range of VDmax between an upper voltage level of 2× VDmax and a lower voltage level of VDmax. The second digital input signal 622 may vary within a voltage range of VDmax between an upper voltage level of VDmax and a lower voltage level of 0, the second digital input signal 622 being in phase with the first digital input signal 612. The second p-type transistor is connected to the second n-type transistor in the series connection. Control terminals of the second p-type transistor and the second n-type transistor may receive DC voltages at VDmax. The series connection of the four transistors is supplied with a DC voltage of 2× VDmax. Accordingly, output terminal 631 of the driver, which the output terminal 631 is coupled to the second p-type transistor and the second n-type transistor. Output signal 632 of the amplifier circuit may vary within a voltage range of 0 and 2× VDmax. In this configuration, the voltage swings between drain-source terminals of each transistor may be in a range of 0-VDmax.

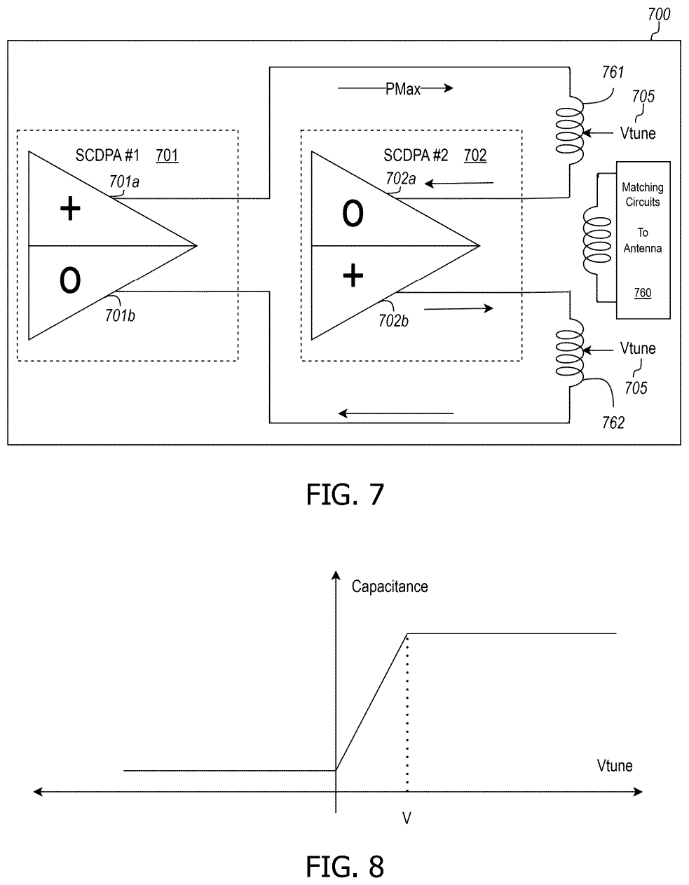

FIG. 7 shows schematically an example of a capacitive RF digital to power converter circuit. The circuit may include a plurality of SCDPAs (e.g. the SCDPA 500). The aspects provided herein are described for an example in which the circuit includes a first SCDPA 701 (e.g. the SCDPA 500) depicted as a SCDPA #1 701 and a second SCDPA 702 (e.g. another SCDPA 500) depicted as a SCDPA #2 702. It is to be noted that the circuit may include more than two SCDPAs, having a 2N number of SCDPAs, N being an integer greater than 0. In examples in which N is greater than 1, the aspects described herein for the first SCDPA apply to a first N number of SCDPAs and the aspects described herein for the second SCDPA apply to a second N number of SCDPAs.

Each SCDPA 701, 702 includes a plurality of SCDPA cells (i.e. plurality of circuits, e.g. SCDPA cells 501a-c) including voltage-controlled capacitance elements to charge or discharge based on received digital input signals.

Each SCDPA 701, 702 may be in a differential configuration, as exemplarily illustrated in FIG. 5. Accordingly, each SCDPA 701, 702 may include a first output terminal 701a, 702a (e.g. the first output terminal 561) connected to first voltage-controlled capacitance elements of the SCDPA cells of the respective SCDPAs. Similarly, each SCDPA 701, 702 may include a second output terminal 701b, 702b (e.g. the second output terminal 562) connected to second voltage-controlled capacitance elements of the SCDPA cells of the respective SCDPAs.

In this illustrative example, the first output terminal 701a of the first SCDPA 701 is coupled to the first output terminal 702a of the second SCDPA 702. Similarly, the second output terminal 701b of the first SCDPA 701 is coupled to the second output terminal 702b of the second SCDPA 702. Digital input signals of each SCDPA 701, 702 is however provided in differential pairs.

In other words, referring to FIG. 5, the first SCDPA 701 is to receive via its first input terminal within its first signal path including its first output terminal 701a, the LO_P signal while the second SCDPA 702 is to receive via its first input terminal within its first signal path including its first output terminal 702a the LO_N signal. Similarly, the first SCDPA 701 is to receive via its second input terminal within its second signal path including its second output terminal 701b, the LO_N signal while the second SCDPA 702 is to receive via its first input terminal within its first signal path including its second output terminal 702b the LO_N signal. In other words, when the output signal of the first SCDPA 701 is at the upper voltage level at the first output terminal 701a, the output signal of the second SCDPA 702 is at the lower voltage level at the first output terminal 702a. Similarly, when the output signal of the first SCDPA 701 is at the upper voltage level at the second output terminal 701b, the output signal of the second SCDPA 702 is at the lower voltage level at the second output terminal 702b. This may also be referred to as, the first input terminal of the first SCDPA 701 is coupled to the second input terminal of the second SCDPA 702 configured to receive the first digital input signal (e.g. LO_P signal) and the second input terminal of the first SCDPA 701 is coupled to the first input terminal of the second SCDPA 702 configured to receive the second digital input signal (e.g. LO_N signal).

As schematically illustrated, the circuit including the first SCDPA 701 and the second SCDPA 702 is connectable to a transformer-based network 760. The first output terminal 701a of the first SCDPA 701 is connected to a first end of a first primary winding 761 of a transformer of the transformer-based network 760, and the first output terminal 702a of the second SCDPA 702 is connected to a second end of the first primary winding 761 to obtain maximum power transfer. Similarly, the second output terminal 701b of the first SCDPA 701 is connected to a first end of a second primary winding 762 of the transformer, and the second output terminal 702b of the second SCDPA 702 is connected to a second end of the second primary winding 762. A secondary winding of the transformer may couple the signal at the first primary winding and the second primary winding to further matching circuits and an antenna. It is to be noted that the first primary winding and the second primary winding may be coupled to separate secondary windings. The separate secondary windings may be a part of separate matching networks.

In various aspects, a voltage (Vₜᵤₙₑ 705) to control capacitance of the voltage-controlled capacitance elements of the first SCDPA 701 and the second SCDPA 702 may be applied from the output terminals 701a-b, 702a-b to the voltage-controlled capacitance elements of the first SCDPA 701 and the second SCDPA 702. Illustratively, a controllable voltage supply circuit may be coupled to the first output terminals 701a, 702a and the second output terminals 701b, 702b to apply Vₜᵤₙₑ 705 voltage to the voltage-controlled capacitive elements of the first SCDPA 701 and the second SCDPA 702 to change their capacitance. Vₜᵤₙₑ 705 voltage may be changed according to two or more designated DC voltages. Vₜᵤₙₑ 705 voltage may be a DC voltage. The controllable voltage supply circuit may change the voltage level of the Vₜᵤₙₑ 705 voltage to operate the first SCDPA 701 and the second SCDPA 702 with voltage-controlled capacitive elements at difference capacitance values. The change of the capacitance may change the quality factor, thereby the response of the circuit.

FIG. 8 shows an exemplary graph representative of an approximate relationship between the capacitance of a voltage-controlled capacitive element and Vₜᵤₙₑ voltage of a voltage-controlled capacitive element such as a MOS varactor, in which the Vₜᵤₙₑ voltage is applied to the voltage-controlled capacitive element to change the capacitance. In this exemplary graph, the capacitance response is provided in a manner that the capacitance of the voltage-controlled capacitive element is at a first capacitance when Vₜᵤₙₑ <0. When Vtune> V volt, the capacitance of the voltage-controlled capacitive element is at a second capacitance higher than the first capacitance.

In various aspects and exemplarily indicated in accordance with FIG. 5 and voltage-controlled capacitive elements of each unit cell, output inverters of each SCDPA 701,702 may toggle between a lower voltage level Vss and an upper voltage level Vdd (e.g. in FIG. 6). In various examples, in particular when the voltage-controlled capacitive elements are MOS varactors, voltage level of the Vₜᵤₙₑ 705 voltage may be set at the lower voltage level Vss, resulting in an effective RMS voltage across the voltage-controlled capacitive elements being at −Vdd/2 voltage, thereby causing a lower effective capacitance (i.e. a first capacitance) for the unit cells. In some examples, voltage level of the Vₜᵤₙₑ 705 voltage may be set at the upper voltage level Vdd, resulting in an effective RMS voltage across the voltage-controlled capacitive elements being at Vdd/2, thereby causing a higher effective capacitance (i.e. a second capacitance higher than the first capacitance) for the unit cells.

The above-mentioned aspects about causing the particular lower and higher effective capacitances may be obtained in a lower complexity manner by employing the first primary winding 761 and the second primary winding 762 with respective center taps. In other words, each of the first primary winding 761 and the second primary winding 762 may include a center tap, and the output of the controllable voltage supply circuit may be coupled to the center taps to provide Vₜᵤₙₑ 705 voltage. Accordingly, DC voltage levels within the circuit, exemplarily providable by the controlled voltage supply circuit may include Vdd and Vss, which voltage levels are used to supply the drivers (e.g. inverters) of the first SCDPA 701 and the second SCDPA 702 and can also be used to control the capacitance of the first SCDPA 701 and the second SCDPA 702. In such an example, a common controllable voltage supply circuit may be coupled to the SCDPAs 701, 702 to supply the drivers and also to control the capacitance.

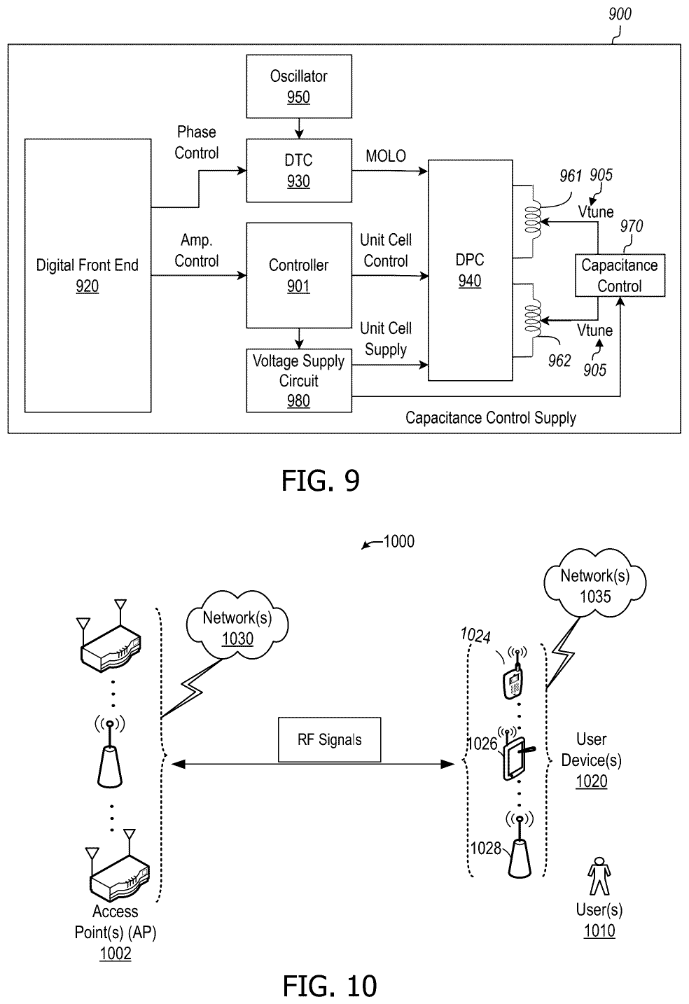

FIG. 9 shows schematically an example of an apparatus of a digital communication circuit. The apparatus 900 is for a DTX architecture. Exemplarily, the apparatus is an apparatus of an IEEE 802.11 communication device or a cellular communication device. The apparatus 900 may include an RF transceiver (e.g. the RF transceiver 400). The apparatus 900 may include a DFE 920 (e.g. the DFE 420), a DTC 930 (e.g. the DTC 430), an LO 950 (e.g. the LO 450), a DPC 940 (e.g. the DPA 440, the SCDPA 500, the circuit 700) and a matching network (e.g. the matching network 460) coupling the output of the DPC 940 to an antenna to transmit RF communication signals including output signals of the DPC 940.

The primary windings 961, 962 of a transformer of the matching network is depicted herein, analogous to aspects provided in accordance with the circuit. In various aspects, the voltage-variable capacitive elements of a first SCDPA (e.g. the first SCDPA 701) and a second SCDPA (e.g. the second SCDPA 702) may be coupled to the first primary winding 961 and the second primary winding 962 in accordance with the aspects provided in accordance with FIG. 7. The apparatus 900 may further include a voltage supply circuit 930, a capacitance control circuit 970, and a controller 901.

The controller 901 may include one or more processors. In various examples, aspects described for the controller 901 may be implemented by a processor of the DFE 920. In various examples, aspects described for the controller 901 may be implemented by a modem. In some examples, the one or more processors may be the one or more processors described in accordance with FIG. 2, such as an application processor, or a DSP. In some examples, a system-on-chip (SoC) may include the controller 901.

The controller 901 may be configured to control operation of the unit cells of the SCDPAs provided in the DPC. The DFE 920 may provide amplitude control codes to the controller 901, and the controller 901 may, based on the amplitude control codes determined by the DFE 920, determine a number of unit cells of SCDPAs to be activated based on the amplitude control codes. The controller 901 may accordingly provide first signals to activate a first subset of the unit cells of the DPC 940, the number of the first subset of the unit cells being the determined number of unit cells. The controller 901 may also provide second signals to deactivate a second subset of the unit cells of the DPC 940. In maximum power operation mode, the controller 901 may provide the first signals to activate the all unit cells. The unit cell control signals that the controller 901 may provide to the DPC 940 may accordingly include the first signals and/or the second signals.

Furthermore, the DFE 920 may further provide the phase control codes to the DTC 930. The DTC 930 may be configured to receive an oscillator signal from an oscillator 950. The oscillator 950 may be a phase-locked loop, or a voltage-controlled oscillator. Based on received phase control codes from the DFE 920, the DTC 930 may phase modulate received oscillator signal and provide an output including modulated oscillator signal (MOLO), that is modulated based on received phase control codes, to the DPC 940. The modulated oscillator signal may include a first digital input signal (e.g. LO_P signal) and a second digital input signal (e.g. LO_N signal) as described in this disclosure, which are to be converted into an analog signal (i.e. a power signal as an output of the DPC 940) via one or more SCDPAs included by the DPC.

The voltage supply circuit 980 may be configured to provide unit cell supply voltage to the DPC 980. The unit cell supply voltage may be the voltage that is supplied to the unit cells for their operation, in particular to the unit cells that are in active operation mode. The unit cell supply voltage may include, in particular, DC voltage used to supply the drivers of the unit cells. As described in various examples, the unit cell supply voltage may include a Vdd voltage (i.e. voltage at an upper voltage level) and a Vss voltage (i.e. voltage at a lower voltage level). Illustratively, the drivers of the unit cells (e.g. each driver being the circuit schematically illustrated in FIG. 6) may be supplied via a voltage between a first supply line and a second supply line. The voltage supply circuit 980 may be configured to supply Vdd voltage to the first supply line and Vss voltage to the second supply line. In some examples, the Vss voltage may be the ground voltage.

The controller 901 may be configured to control the voltage supply circuit 980 to cause the unit cell supply voltage to provide to the DPA 940. Furthermore, the controller 901 may be coupled to the capacitance control circuit 970, and the controller 901 may be configured to control the capacitance control circuit 970 to cause a change at the capacitance of the unit cells of the DPA 940. The capacitance control circuit 970 may be coupled to the voltage supply circuit 980 to receive a voltage supply. The capacitance control circuit 970 may provide an output including Vₜᵤₙₑ 905.

The capacitance control circuit 970 may be configured to apply various levels of DC voltage to the output terminals (e.g. the first output terminal 561, the first output terminals 701a, 702a, the second output terminal 562, the second output terminals 701b, 702b). In particular, the capacitance control circuit 970 may be configured to selectively apply a first voltage at a first voltage level and a second voltage at a second voltage level. The first voltage level may cause the capacitance of the voltage-controlled capacitive elements of the unit cells at a first capacitance level and the second voltage level may cause the capacitance of the voltage-controlled capacitive elements at a second capacitance level. The controller 901 may determine the voltage to be applied by the capacitance control circuit 970 and control the capacitance control circuit 970 by causing the capacitance control circuit 970 to apply a determined voltage level.

In the structure described in accordance with the circuit 700, in which each primary winding 961, 962 including a center tap, the Vₜᵤₙₑ 905 (i.e. voltage applied by the capacitance control circuit 970) may include Vdd voltage as the first voltage level and Vss voltage as the second voltage level. The skilled person would recognize that in such an example, the capacitance control circuit 970 may include switching devices (e.g. one or more transistors) to switch Vₜᵤₙₑ 905 between Vdd voltage and Vss voltage by using the switching devices coupled to the voltage supply circuit 980 to receive supply voltage (e.g. Vdd voltage).

In particular, the controller 901 may determine a capacitance value for the voltage-controlled capacitive elements and cause the capacitance control circuit 970 to apply a Vₜᵤₙₑ 905 to a voltage level based on the determined capacitance value. In various examples, the controller 901 may determine a voltage value to be applied by the capacitance control circuit 970. The controller 901 may cause the capacitance control circuit to apply a Vₜᵤₙₑ 905 at a determined voltage value. Accordingly, the controller 901 may cause variation in the capacitance of the voltage-controlled capacitive elements.

In some aspects, the controller 901 may further control the voltage supply circuit 980 to cause the voltage supply circuit 980 to provide a voltage that may be different from one of Vdd or Vss. The voltage supply circuit may be configured to supply variable voltage, at least to the capacitance control circuit 970. The controller 901 may control the voltage supply circuit 980 to vary the voltage supplied to the capacitance control circuit 970, to vary the capacitance of the voltage controlled capacitive elements.

In various aspects, the capacitance control operation described herein involving the controller 901, the voltage supply circuit 980, and the capacitance control circuit 970, to vary the capacitance of the voltage-controlled capacitive elements by varying the voltage applied to the voltage-controlled capacitive elements may be provided in various modes. These modes may be defined or determined exemplarily during design and/or manufacturing of the apparatus 900 or the communication device including the apparatus 900.

In modes that are predefined or predetermined, various capacitance values or voltage levels may be designated for operation and stored in a memory (e.g. the memory 214) that is not depicted in this figure. Exemplarily, the controller 901 may control the voltage supply circuit 980 to supply voltage at one or more predefined or predetermined voltage levels to the capacitance control circuit 970. Alternatively, or additionally, the controller 901 may control the capacitance control circuit 970 to apply voltage at one or more predefined or predetermined voltage levels to the capacitance control circuit 970.

The one or more predefined or predetermined voltage levels may include at least a first voltage level to be applied to change the capacitance. It is to be noted that in one example, the Vₜᵤₙₑ 905 at a first voltage level may include a voltage V that is predefined or predetermined and the Vₜᵤₙₑ 905 may be 0 (zero) as a second voltage level. The one or more predefined or predetermined voltage levels may include further voltage levels, each associated with a particular operation mode associated with the operation of the apparatus 900 or the communication device including the apparatus 900. It is further to be noted that predefined voltage levels may be implemented by a hardware circuitry varying a voltage applied at a first instance of time to another voltage applied at a second instance of time (e.g. via switching a divider network). Exemplarily, the capacitance control circuit 970 may be supplied by the voltage supply circuit 980 with a fixed voltage and the capacitance control circuit 970 may be configured to apply at least one voltage that is different from the voltage supplied by the voltage supply circuit 980 to vary the applied voltage.

In the context of various operation modes, the controller 901 may cause the capacitance control circuit 970 to apply various voltages defined or determined for various operation modes. Illustratively, a memory may include information representative of a mapping to various voltage levels or capacitance values (e.g. a look-up table) for various operation mode. An exemplary illustration may be in a reference to FIG. 8, a first operation mode may include a first operation mode with a first predefined voltage level being V=0 volt applied by the capacitance control circuit 970 and a second operation mode with a second predefined voltage level being V=V volts applied by the capacitance control circuit 970.

The controller 901 may determine the operation mode based on its operations, exemplarily by an instruction received from another processor or the DFE 920. The controller 901 may, in particular, determine the operation mode based on various parameters of RF communication to be used to transmit RF communication signals including the output of the DPA 940. In particular, the RF transmission to transmit RF communication signals may be provided within a designated frequency band. The controller 901 may determine the operation mode based on the frequency band designated for the RF transmission. Illustratively, for an RF transmission within a first frequency band, the controller 901 may determine the first operation mode and cause the capacitance control circuit 970 to apply Vₜᵤₙₑ 905 at a first voltage level. For an RF transmission within a second frequency band, the controller 901 may determine the second operation mode and cause the capacitance control circuit 970 to apply Vₜᵤₙₑ 905 at a second voltage level.

In particular, in an example in which the communication device is an IEEE 802.11 communication device and the apparatus 900 is configured to RF communication in accordance with IEEE 802.11 radio communication, illustratively, when RF transmission is within 2.4 GHZ frequency band, the controller 901 may determine the second operation mode and accordingly cause the capacitance control circuit 970 to apply Vₜᵤₙₑ 905 at V volts and accordingly cause a higher capacitance level for the voltage-controlled capacitive elements. When RF transmission is within 5 GHz or 6 GHz frequency band, the controller 901 may determine the first operation mode and accordingly cause the capacitance control circuit 970 to apply Vₜᵤₙₑ 905 at 0 volt, and accordingly cause a lower capacitance level for the voltage-controlled capacitance elements.

FIG. 10 is a network diagram illustrating an example network environment including communication devices as exemplarily described herein, according to some example embodiments of the present disclosure. Wireless network 1000 may include one or more user devices 1020 and one or more access points(s) (AP) 1002, which may communicate in accordance with IEEE 802.11 communication standards. The user device(s) 1020 may be mobile devices that are non-stationary (e.g., not having fixed locations) or may be stationary devices. Exemplarily, the one or more user devices 1020 and/or one or more APs 1002 may include an apparatus of a communication device as described herein (e.g. the apparatus 900).

One or more illustrative user device(s) 1020 and/or AP(s) 1002 may be operable by one or more user(s) 1010. It should be noted that any addressable unit may be a station (STA). An STA may take on multiple distinct characteristics, each of which shape its function. For example, a single addressable unit might simultaneously be a portable STA, a quality-of-service (QoS) STA, a dependent STA, and a hidden STA. The one or more illustrative user device(s) 1020 and the AP(s) 1002 may be STAs. The one or more illustrative user device(s) 1020 and/or AP(s) 1002 may operate as a personal basic service set (PBSS) control point/access point (PCP/AP). The user device(s) 1020 (e.g., 1024, 1026, or 1028) and/or AP(s) 1002 may include any suitable processor-driven device including, but not limited to, a mobile device or a non-mobile, e.g., a static device. For example, user device(s) 1020 and/or AP(s) 1002 may include, a user equipment (UE), a station (STA), an access point (AP), a software enabled AP (SoftAP), a personal computer (PC), a wearable wireless device (e.g., bracelet, watch, glasses, ring, etc.), a desktop computer, a mobile computer, a laptop computer, an Ultrabook™ computer, a notebook computer, a tablet computer, a server computer, a handheld computer, a handheld device, an internet of things (IoT) device, a sensor device, a PDA device, a handheld PDA device, an on-board device, an off-board device, a hybrid device (e.g., combining cellular phone functionalities with PDA device functionalities), a consumer device, a vehicular device, a non-vehicular device, a mobile or portable device, a non-mobile or non-portable device, a mobile phone, a cellular telephone, a PCS device, a PDA device which incorporates a wireless communication device, a mobile or portable GPS device, a DVB device, a relatively small computing device, a non-desktop computer, a “carry small live large” (CSLL) device, an ultra mobile device (UMD), an ultra mobile PC (UMPC), a mobile internet device (MID), an “origami” device or computing device, a device that supports dynamically composable computing (DCC), a context-aware device, a video device, an audio device, an A/V device, a set-top-box (STB), a blu-ray disc (BD) player, a BD recorder, a digital video disc (DVD) player, a high definition (HD) DVD player, a DVD recorder, a HD DVD recorder, a personal video recorder (PVR), a broadcast HD receiver, a video source, an audio source, a video sink, an audio sink, a stereo tuner, a broadcast radio receiver, a flat panel display, a personal media player (PMP), a digital video camera (DVC), a digital audio player, a speaker, an audio receiver, an audio amplifier, a gaming device, a data source, a data sink, a digital still camera (DSC), a media player, a smartphone, a television, a music player, or the like. Other devices, including smart devices such as lamps, climate control, car components, household components, appliances, etc. may also be included in this list.

As used herein, the term “Internet of Things (IoT) device” is used to refer to any object (e.g., an appliance, a sensor, etc.) that has an addressable interface (e.g., an Internet protocol (IP) address, a Bluetooth identifier (ID), a near-field communication (NFC) ID, etc.) and can transmit information to one or more other devices over a wired or wireless connection. An IoT device may have a passive communication interface, such as a quick response (QR) code, a radio-frequency identification (RFID) tag, an NFC tag, or the like, or an active communication interface, such as a modem, a transceiver, a transmitter-receiver, or the like. An IoT device can have a particular set of attributes (e.g., a device state or status, such as whether the IoT device is on or off, open or closed, idle or active, available for task execution or busy, and so on, a cooling or heating function, an environmental monitoring or recording function, a light-emitting function, a sound-emitting function, etc.) that can be embedded in and/or controlled/monitored by a central processing unit (CPU), microprocessor, ASIC, or the like, and configured for connection to an IoT network such as a local ad-hoc network or the Internet. For example, IoT devices may include, but are not limited to, refrigerators, toasters, ovens, microwaves, freezers, dishwashers, dishes, hand tools, clothes washers, clothes dryers, furnaces, air conditioners, thermostats, televisions, light fixtures, vacuum cleaners, sprinklers, electricity meters, gas meters, etc., so long as the devices are equipped with an addressable communications interface for communicating with the IoT network. IoT devices may also include cell phones, desktop computers, laptop computers, tablet computers, personal digital assistants (PDAs), etc. Accordingly, the IoT network may be comprised of a combination of “legacy” Internet-accessible devices (e.g., laptop or desktop computers, cell phones, etc.) in addition to devices that do not typically have Internet-connectivity (e.g., dishwashers, etc.).

The user device(s) 1020 and/or AP(s) 1002 may also include mesh stations in, for example, a mesh network, in accordance with one or more IEEE 802.11 standards and/or 3GPP standards.

Any of the user device(s) 1020 (e.g., user devices 1024, 1026, 1028), and AP(s) 1002 may be configured to communicate with each other via one or more communications networks 1030 and/or 1035 wirelessly or wired. The user device(s) 1020 may also communicate peer-to-peer or directly with each other with or without the AP(s) 1002. Any of the communications networks 1030 and/or 1035 may include, but not limited to, any one of a combination of different types of suitable communications networks such as, for example, broadcasting networks, cable networks, public networks (e.g., the Internet), private networks, wireless networks, cellular networks, or any other suitable private and/or public networks. Further, any of the communications networks 1030 and/or 1035 may have any suitable communication range associated therewith and may include, for example, global networks (e.g., the Internet), metropolitan area networks (MANs), wide area networks (WANs), local area networks (LANs), or personal area networks (PANs). In addition, any of the communications networks 1030 and/or 1035 may include any type of medium over which network traffic may be carried including, but not limited to, coaxial cable, twisted-pair wire, optical fiber, a hybrid fiber coaxial (HFC) medium, microwave terrestrial transceivers, radio frequency communication mediums, white space communication mediums, ultra-high frequency communication mediums, satellite communication mediums, or any combination thereof.

Any of the user device(s) 1020 (e.g., user devices 1024, 1026, 1028) and AP(s) 1002 may include one or more communications antennas. The one or more communications antennas may be any suitable type of antennas corresponding to the communications protocols used by the user device(s) 1020 (e.g., user devices 1024, 1026 and 1028), and AP(s) 1002. Some non-limiting examples of suitable communications antennas include Wi-Fi antennas, Institute of Electrical and Electronics Engineers (IEEE) 802.11 family of standards compatible antennas, directional antennas, non-directional antennas, dipole antennas, folded dipole antennas, patch antennas, multiple-input multiple-output (MIMO) antennas, omnidirectional antennas, quasi-omnidirectional antennas, or the like. The one or more communications antennas may be communicatively coupled to a radio component to transmit and/or receive signals, such as communications signals to and/or from the user devices 1020 and/or AP(s) 1002.

Any of the user device(s) 1020 (e.g., user devices 1024, 1026, 1028), and AP(s) 1002 may be configured to perform directional transmission and/or directional reception in conjunction with wirelessly communicating in a wireless network. Any of the user device(s) 1020 (e.g., user devices 1024, 1026, 1028), and AP(s) 1002 may be configured to perform such directional transmission and/or reception using a set of multiple antenna arrays (e.g., DMG antenna arrays or the like). Each of the multiple antenna arrays may be used for transmission and/or reception in a particular respective direction or range of directions. Any of the user device(s) 1020 (e.g., user devices 1024, 1026, 1028), and AP(s) 1002 may be configured to perform any given directional transmission towards one or more defined transmit sectors. Any of the user device(s) 1020 (e.g., user devices 1024, 1026, 1028), and AP(s) 1002 may be configured to perform any given directional reception from one or more defined receive sectors.

MIMO beamforming in a wireless network may be accomplished using RF beamforming and/or digital beamforming. In some embodiments, in performing a given MIMO transmission, user devices 1020 and/or AP(s) 1002 may be configured to use all or a subset of its one or more communications antennas to perform MIMO beamforming.

Any of the user devices 1020 (e.g., user devices 1024, 1026, 1028), and AP(s) 1002 may include any suitable radio and/or transceiver for transmitting and/or receiving radio frequency (RF) signals in the bandwidth and/or channels corresponding to the communications protocols utilized by any of the user device(s) 1020 and AP(s) 1002 to communicate with each other. The radio components may include hardware and/or software to modulate and/or demodulate communications signals according to pre-established transmission protocols. The radio components may further have hardware and/or software instructions to communicate via one or more Wi-Fi and/or Wi-Fi direct protocols, as standardized by the Institute of Electrical and Electronics Engineers (IEEE) 802.11 standards. In certain example embodiments, the radio component, in cooperation with the communications antennas, may be configured to communicate via 2.4 GHz channels (e.g. 802.11b, 802.11 g, 802.11n, 802.11ax), 5 GHz channels (e.g. 802.11n, 802.11ac, 802.11ax, 802.11be, etc.), 6 GHZ channels (e.g., 802.11ax, 802.11be, etc.), or 60 GHZ channels (e.g. 802.11ad, 802.11ay). 800 MHZ channels (e.g. 802.11ah). The communications antennas may operate at 28 GHZ and 40 GHz. It should be understood that this list of communication channels in accordance with certain 802.11 standards is only a partial list and that other 802.11 standards may be used (e.g., Next Generation Wi-Fi, or other standards). In some embodiments, non-Wi-Fi protocols may be used for communications between devices, such as Bluetooth, dedicated short-range communication (DSRC), Ultra-High Frequency (UHF) (e.g. IEEE 802.11af, IEEE 802.22), white band frequency (e.g., white spaces), or other packetized radio communications. The radio component may include any known receiver and baseband suitable for communicating via the communications protocols. The radio component may further include a low noise amplifier (LNA), additional signal amplifiers, an analog-to-digital (A/D) converter, one or more buffers, and digital baseband.

In accordance with various aspects provided herein, a user device 1020 may be in communication with one or more APs 1002, in which the user device 1020 and/or the one or more APs 1002 may include the apparatus 900, which is to be referred to as a communication device in accordance with FIG. 10. The controller 901 of the communication device may determine to vary the capacitance of voltage-controlled variable capacitive elements of the DPC 940 during its operation and may cause a change at the capacitance of the voltage-controlled variable capacitive elements. Exemplarily, the controller 901 may be configured to determine to vary the capacitance based on above-mentioned communication channels to be used to transmit RF communication signals.

It is to be noted that load-pull simulation results may provide valuable information about the performance of PAs under various load conditions. In load-pull simulations, the impedance presented to the PA circuit (e.g. output impedance for the circuit 700) is varied, and the resulting performance may be analyzed. Each contour line depicted in load-pull results may be representative of a constant value of one of the performance parameters.

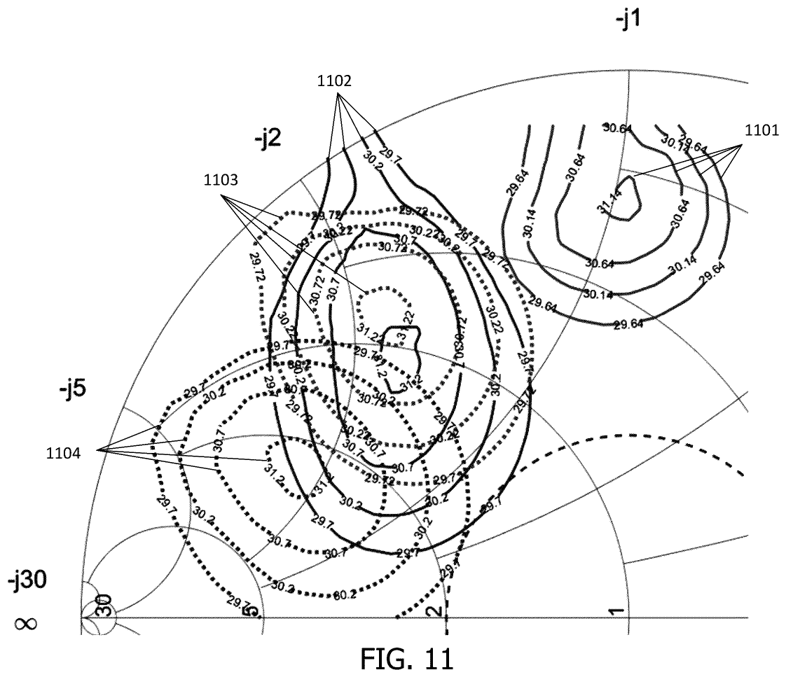

FIG. 11 shows schematically load-pull simulation results obtained with a DPA in accordance with aspects provided herein (e.g. the circuit 700). Each contour is representative of maximum power associated with the respective load-pull simulation results. Only a related portion of smith charts are provided for brevity in this disclosure. Solid contours at the right-hand side 1101 are representative of the load-pull simulation results with the DPA for RF transmission on a frequency band of 2.45 GHZ with an applied first voltage causing a lower capacitance state. Contours read from the most inner one to the most outer one: 31.14, 30.64, 30.14, 29.64. Solid contours at the middle 1102 are representative of the load-pull simulation results with the DPA for RF transmission on a frequency band of 6 GHZ with the applied first voltage causing the lower capacitance state. Contours read from the most inner one to the most outer one: 31.2, 30.7, 30.2, 29.7.

Dashed contours at the middle 1103 are representative of the load-pull simulation results with the DPA for RF transmission on the frequency band of 2.45 GHZ with an applied second voltage causing a higher capacitance state. Contours read from the most inner one to the most outer one: 31.22, 30.72, 30.22, 29.72. Dashed contours at the left-hand side 1104 are representative of the load-pull simulation results with the DPA for RF transmission on the frequency band of 6 GHZ with the applied second voltage causing the higher capacitance state. Contours read from the most inner one to the most outer one: 31.2, 30.7, 30.2, 29.7.

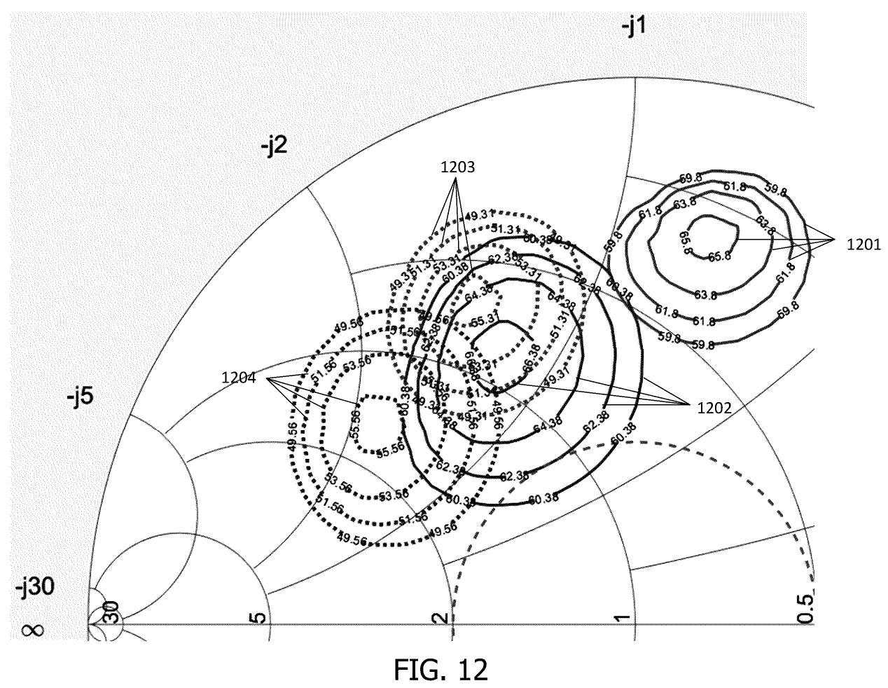

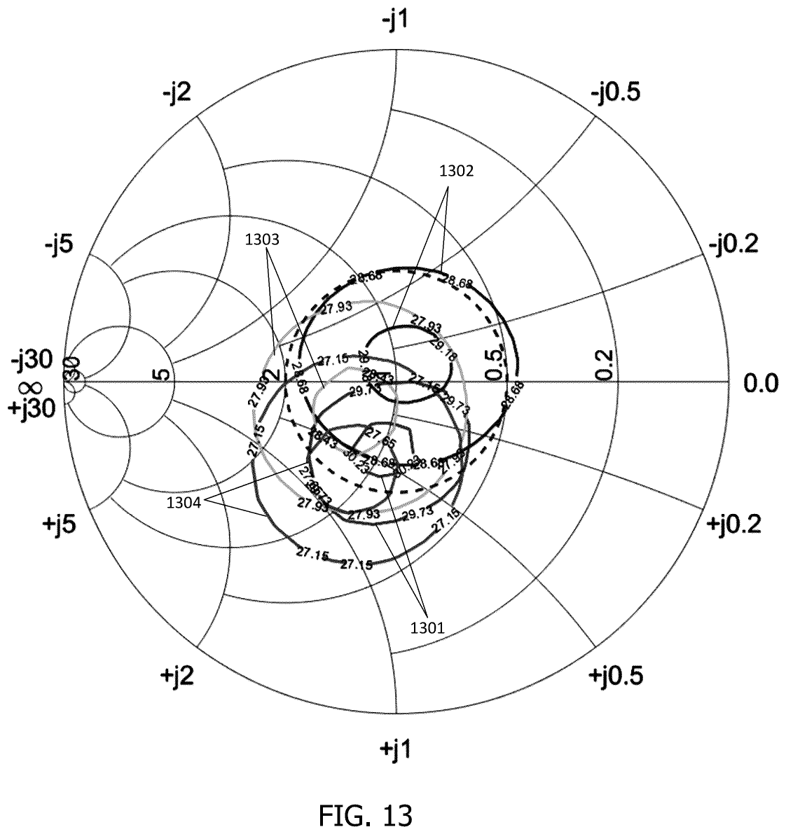

FIG. 12 shows schematically load-pull simulation results obtained with a DPA in accordance with aspects provided herein (e.g. the circuit 700). Each contour is representative of power efficiency associated with the respective load-pull simulation results. Solid contours at the right-hand side 1201 are representative of the load-pull simulation results with the DPA for RF transmission on a frequency band of 2.45 GHZ with an applied first voltage (V_{tune,1}) causing a lower capacitance state. Contours read from the most inner one to the most outer one: 65.8, 63.8, 61.8, 59.8. Solid contours at the middle 1202 are representative of the load-pull simulation results with the DPA for RF transmission on a frequency band of 6 GHz with the applied first voltage (V_{tune,1}) causing the lower capacitance state. Contours read from the most inner one to the most outer one: 66.38, 64.38, 62.38, 60.38.

Dashed contours at the middle 1203 are representative of the load-pull simulation results with the DPA for RF transmission on the frequency band of 2.45 GHZ with an applied second voltage (V_{tune,2}) causing a higher capacitance state. Contours read from the most inner one to the most outer one: 55.31, 53.31, 51.31, 49.31. Dashed contours at the left-hand side 1204 are representative of the load-pull simulation results with the DPA for RF transmission on the frequency band of 6 GHz with the applied second voltage (V_{tune,2}) causing the higher capacitance state. Contours read from the most inner one to the most outer one: 55.56, 53.56, 51.56, 49.56.

As can be seen from FIGS. 11 and 12 collectively, when the capacitance states are the same, the contours for the frequency band 2.45 GHZ and the contours for the frequency band 6 GHz (1201 and 1202; or 1203 and 1204 in pairs respectively) are provided at relatively far from each other, indicating that the performance (maximum power and power efficiency respectively) obtained from the DPA varies significantly. Thereby, it may not be effective to use the same DPA for these bands. On the other hand, when the capacitance states are different, namely when the capacitance state is at the lower capacitance state for the frequency band of 6 GHZ and at the higher capacitance state for the frequency band of 2.45 GHZ, the contours for the frequency band 2.45 GHZ and the contours for the frequency band 6 GHZ (1203 and 1202 respectively) are provided relatively near, within approximately the same region. This is indicative of that the performance (maximum power and power efficiency respectively) obtained from the DPA is within a designated region. Accordingly, the same DPA may be used for both of these frequency bands by changing the capacitance of the variable capacitive elements based on the frequency band.

FIG. 13 shows schematically load-pull simulation results obtained with a DPA in accordance with aspects provided herein (e.g. the circuit 700) with an initial matching network. Each contour is representative of maximum power associated with the respective load-pull simulation results. The first contours 1301 are representative of the load-pull simulation results with the DPA for RF transmission on a frequency band of 2.45 GHZ with an applied first voltage (V_{tune,1}) causing a higher capacitance state. The first contours 1301 read from the most inner one to the most outer one: 30.23, 29.73. The second contours 1302 are representative of the load-pull simulation results with the DPA for RF transmission on a frequency band of 5 GHZ with an applied second voltage (V_{tune,2}) causing a lower capacitance state. The second contours 1302 read from the most inner one to the most outer one: 29.18, 28.68.

The third contours 1303 are representative of the load-pull simulation results with the DPA for RF transmission on a frequency band of 6 GHZ with the applied second voltage (V_{tune,2}) causing the lower capacitance state. The third contours 1303 read from the most inner one to the most outer one: 28.43, 27.93. The fourth contour 1304 are representative of the load-pull simulation results with the DPA for RF transmission on a frequency band of 7 GHZ with the applied second voltage (V_{tune,2}) causing the lower capacitance state. The fourth contours 1304 read from the most inner one to the most outer one: 27.65, 27.15.

As can be seen, with the initial matching network, by applying different Vₜᵤₙₑ voltages, the DPA may be used in a desired region for multiple frequency bands. Illustratively, the DPA may be used for, by causing a first capacitance, the frequency band of 2.45 GHZ, while the DPA may further be used for, by causing a second capacitance, the frequency bands of 5-7 GHZ.

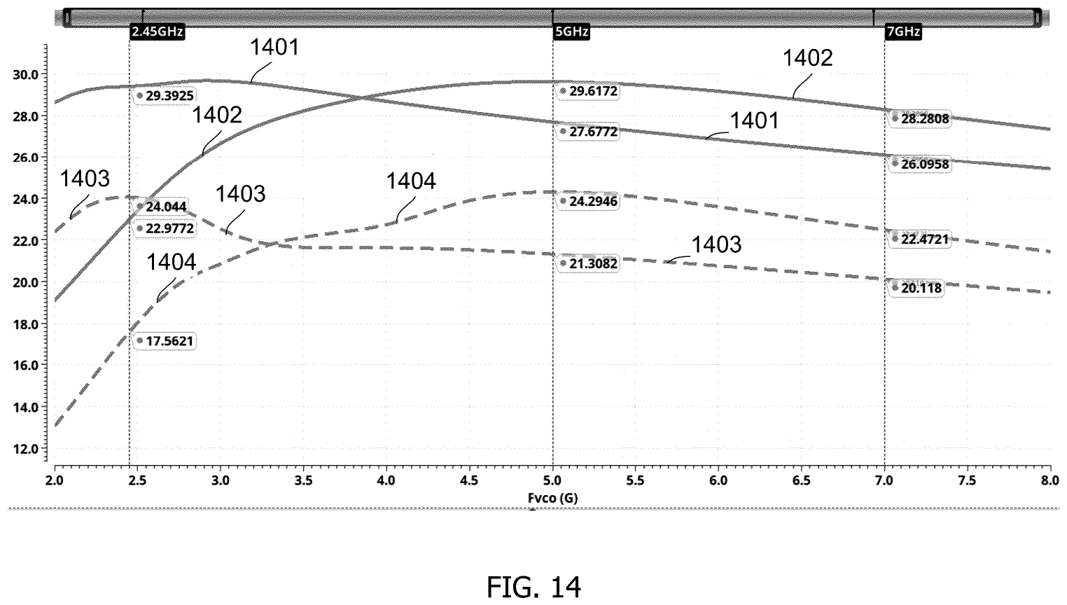

FIG. 14 shows schematically frequency response graphs of a DPA in accordance with aspects provided herein (e.g. the circuit 700) simulated with an initial matching network. For each graph, frequency response parameters crossing 2.45 GHZ, 5 GHZ, and 7 GHz lines are provided. First curve 1401 shows the frequency response of the circuit at maximum power with an applied first voltage (V_{tune,1}) causing a higher capacitance state. Second curve 1402 shows the frequency response of the circuit at maximum power with an applied second voltage (V_{tune,2}) causing a lower capacitance state. Third curve 1403 shows the frequency response of the circuit with half amplitude codes (e.g. half of maximum power) with the applied first voltage (V_{tune,1}) causing the higher capacitance state. Fourth curve 1404 shows the frequency response of the circuit with half amplitude codes (e.g. half of maximum power) with the applied second voltage (V_{tune,2}) causing the lower capacitance state

The detailed description refers to the accompanying drawings that show, by way of illustration, specific details and aspects of this disclosure in which the disclosure may be practiced. Other aspects may be utilized and structural, logical, and electrical changes may be made without departing from the scope of the disclosure. The various aspects of this disclosure are not necessarily mutually exclusive, as some aspects of this disclosure can be combined with one or more other aspects of this disclosure to form new aspects.

The word “exemplary” is used herein to mean “serving as an example, instance, or illustration”. Any aspect of the disclosure or design described herein as “exemplary” is not necessarily to be construed as preferred or advantageous over other aspects or designs.

Throughout the drawings, it should be noted that like reference numbers are used to depict the same or similar elements, features, and structures, unless otherwise noted.

The words “plurality” and “multiple” in the description or the claims expressly refer to a quantity greater than one. The terms “group (of)”, “set [of]”, “collection (of)”, “series (of)”, “sequence (of)”, “grouping (of)”, etc., and the like in the description or in the claims refer to a quantity equal to or greater than one, i.e. one or more. Any term expressed in a plural form that does not expressly state “plurality” or “multiple” likewise refers to a quantity equal to or greater than one.

As used herein, “memory” is understood as a non-transitory computer-readable medium in which data or information can be stored for retrieval. References to “memory” included herein may thus be understood as referring to volatile or non-volatile memory, including random access memory (“RAM”), read-only memory (“ROM”), flash memory, solid-state storage, magnetic tape, hard disk drive, optical drive, etc., or any combination thereof. Furthermore, registers, shift registers, processor registers, data buffers, etc., are also embraced herein by the term memory. A single component referred to as “memory” or “a memory” may be composed of more than one different type of memory, and thus may refer to a collective component including one or more types of memory. Any single memory component may be separated into multiple collectively equivalent memory components, and vice versa. Furthermore, while memory may be depicted as separate from one or more other components (such as in the drawings), memory may also be integrated with other components, such as on a common integrated chip or a controller with an embedded memory.

In the context of this disclosure, the term “process” may be used, for example, to indicate a method. Illustratively, any process described herein may be implemented as a method (e.g., a channel estimation process may be understood as a channel estimation method). Any process described herein may be implemented as a non-transitory computer readable medium including instructions configured, when executed, to cause one or more processors to carry out the process (e.g., to carry out the method).

“The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The terms “group (of)”, “set (of)”, “collection (of)”, “series (of)”, “sequence (of)”, “grouping (of)”, etc., and the like in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

Unless explicitly specified, the term “transmit” encompasses both direct (point-to-point) and indirect transmission (via one or more intermediary points). Similarly, the term “receive” encompasses both direct and indirect reception. Furthermore, the terms “transmit,” “receive,” “communicate,” and other similar terms encompass both physical transmission (e.g., the transmission of radio signals) and logical transmission (e.g., the transmission of digital data over a logical software-level connection). For example, a processor or controller may transmit or receive data over a software-level connection with another processor or controller in the form of radio signals, where the physical transmission and reception is handled by radio-layer components such as RF transceivers and antennas, and the logical transmission and reception over the software-level connection is performed by the processors or controllers. The term “communicate” encompasses one or both of transmitting and receiving, i.e., unidirectional or bidirectional communication in one or both of the incoming and outgoing directions. The term “calculate” encompasses both ‘direct’ calculations via a mathematical expression/formula/relationship and ‘indirect’ calculations via lookup or hash tables and other array indexing or searching operations.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

As used herein, a signal that is “indicative of” a value or other information may be a digital or analog signal that encodes or otherwise communicates the value or other information in a manner that can be decoded by and/or cause a responsive action in a component receiving the signal. The signal may be stored or buffered in computer readable storage medium prior to its receipt by the receiving component and the receiving component may retrieve the signal from the storage medium. Further, a “value” that is “indicative of” some quantity, state, or parameter may be physically embodied as a digital signal, an analog signal, or stored bits that encode or otherwise communicate the value.

As used herein, a signal may be transmitted or conducted through a signal chain in which the signal is processed to change characteristics such as phase, amplitude, frequency, and so on. The signal may be referred to as the same signal even as such characteristics are adapted. In general, so long as a signal continues to encode the same information, the signal may be considered as the same signal. For example, a transmit signal may be considered as referring to the transmit signal in baseband, intermediate, and radio frequencies.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

As utilized herein, terms “module”, “component,” “system,” “circuit,” “element,” “slice,” “circuitry,” and the like are intended to refer to a set of one or more electronic components, a computer-related entity, hardware, software (e.g., in execution), and/or firmware. For example, circuitry or a similar term can be a processor, a process running on a processor, a controller, an object, an executable program, a storage device, and/or a computer with a processing device. By way of illustration, an application running on a server and the server can also be circuitry. One or more circuits can reside within the same circuitry, and circuitry can be localized on one computer and/or distributed between two or more computers. A set of elements or a set of other circuits can be described herein, in which the term “set” can be interpreted as “one or more.”

The term “antenna” or “antenna structure”, as used herein, may include any suitable configuration, structure and/or arrangement of one or more antenna elements, components, units, assemblies and/or arrays. In some aspects, the antenna may implement transmit and receive functionalities using separate transmit and receive antenna elements. In some aspects, the antenna may implement transmit and receive functionalities using common and/or integrated transmit/receive elements. The antenna may include, for example, a phased array antenna, a single element antenna, a set of switched beam antennas, and/or the like.

It will be understood that when an element is referred to as being “connected” or “coupled” to another element, it can be physically connected or coupled to the other element such that current and/or electromagnetic radiation (e.g., a signal) can flow along a conductive path formed by the elements. Intervening conductive, inductive, or capacitive elements may be present between the element and the other element when the elements are described as being coupled or connected to one another. Further, when coupled or connected to one another, one element may be capable of inducing a voltage or current flow or propagation of an electro-magnetic wave in the other element without physical contact or intervening components. Further, when a voltage, current, or signal is referred to as being “applied” to an element, the voltage, current, or signal may be conducted to the element by way of a physical connection or by way of capacitive, electro-magnetic, or inductive coupling that does not involve a physical connection.

It will be understood that an inductive element (e.g. an inductor, a winding of a transformer) described herein includes an electronic component (e.g. a passive electric component) that stores energy in its magnetic field when electric current flows through it. Inductors are characterized by their inductance (e.g. intrinsic inductance), a measure of their ability to store electrical energy in their magnetic field, and typically have units of Henrys (H).

In example 1, the subject matter includes a capacitive digital-to-analog converter (CDAC). The subject matter may be, in particular, an RF-CDAC, a switched capacitor DPA, or a digital-to-power converter. The subject matter may include: a plurality of circuits configured to receive a digital signal to be converted into an analog signal, can optionally include that each circuit of the plurality of circuits includes: a variable capacitive element; and a driver configured to cause the variable capacitive element to be charged or discharged to convert the received digital signal into the analog signal.

In example 2, the subject matter of example 1, can optionally include that each circuit further includes: a logic component configured to provide the received digital signal to a signal path coupled to the driver based on a received control signal.

In example 3, the subject matter of example 1 or example 2, can optionally include that the CDAC includes an output terminal coupled to the variable capacitive element of each circuit; can optionally include that the variable capacitive element is a voltage-variable capacitive element.

In example 4, the subject matter of example 3, can optionally include that a capacitance of the voltage-variable capacitive elements is controlled by a voltage applied to the output terminal.

In example 5, the subject matter of example 4, can optionally include that the driver includes an inverter.

In example 6, the subject matter of example 5, can optionally include that the inverter is configured to provide an inverted digital signal varying between an upper voltage level and a lower voltage level; can optionally include that the voltage applied to the output terminal is at the upper voltage level.

In example 7, the subject matter of example 5, can optionally include that the inverter is configured to provide an inverted digital signal varying between an upper voltage level and a lower voltage level; can optionally include that the voltage applied to the output terminal is at the lower voltage level.

In example 8, the subject matter of any one of examples 3 to 7, can optionally include that the voltage-variable capacitive element includes a metal oxide semiconductor (MOS) varactor.

In example 9, the subject matter of any one of examples 3 to 8, can optionally include that the received digital signal includes a first digital signal and a second digital signal that is a differential pair of the first digital signal; can optionally include that the variable capacitive element is a first variable capacitive element, and the output terminal is a first output terminal; can optionally include that the CDAC further includes a second voltage-variable capacitive element coupled to a second output terminal to convert the second digital signal into the analog signal.

In example 10, the subject matter of example 9, may further include a further driver configured to cause the further voltage-variable capacitive element to be charged or discharged based on the second digital signal.

In example 11, the subject matter of example 10, can optionally include that a capacitance of the further voltage-variable capacitive element is controlled by a voltage applied to the second output terminal.

In example 12, the subject matter of example 11, can optionally include that the voltage applied to the first output terminal and the voltage applied to the second output terminal are equal.

In example 13, the subject matter of any one of examples 10 to 12, may further include: a further logic component configured to provide the second digital signal to a second signal path coupled to the further driver.

In example 14, the subject matter of example 13, can optionally include that the logic component and the further logic component is controlled by the same control signal.

In example 15, the subject matter of any one of examples 1 to 14, can optionally include that received digital signal includes an oscillator signal.

In example 16, the subject matter includes an apparatus of a digital communication circuit. The apparatus may include: a capacitive digital-to-analog converter (CDAC) may include: a plurality of circuits configured to receive a digital signal to be converted into an analog signal, can optionally include that each circuit of the plurality of circuits includes: a variable capacitive element; a driver configured to cause the variable capacitive element to be charged or discharged to convert the received digital signal into the analog signal; and a controller configured activate or deactivate each circuit of the plurality of circuits.

In example 17, the subject matter of example 16, can optionally include that the controller is configured to activate or deactivate each circuit of the plurality of circuits based on amplitude control information.

In example 18, the subject matter of example 17, may further include: a digital front end configured to provide the amplitude control information based on baseband signals.

In example 19, the subject matter of example 17 or example 18, may further include: an oscillator configured to generate an oscillator signal; a digital-to-time converter configured to modulate generated oscillator signal based on phase control information.

In example 20, the subject matter of example 19, can optionally include that the digital front end is configured to provide the phase control information based on the baseband signals.

In example 21, the subject matter of any one of examples 16 to 20, can optionally include that the variable capacitive element is a voltage-variable capacitive element; can optionally include that the voltage-variable capacitive elements of the plurality of circuits are coupled to an output terminal; can optionally include that the apparatus further includes a transformer-based matching network may include a transformer with a primary winding coupled to the output terminal.

In example 22, the subject matter of example 21, may further include: a voltage supply circuit configured to supply a voltage to the output terminal.

In example 23, the subject matter of example 22, can optionally include that the primary winding of the transformer includes a center tap, and can optionally include that the voltage supply circuit is configured to supply the voltage to the center tap.

In example 24, the subject matter of example 23, can optionally include that the driver is configured to provide a driver signal varying between an upper voltage level and a lower voltage level; can optionally include that the supply voltage is at the upper voltage level.

In example 25, the subject matter of example 23, can optionally include that the driver is configured to provide a driver signal varying between an upper voltage level and a lower voltage level; can optionally include that the supply voltage is at the lower voltage level.

In example 26, the subject matter of example any one of examples 22 to 25, can optionally include that each circuit further includes a further voltage-variable capacitive element configured to discharge to a further output terminal, and a further driver configured to drive the further voltage-variable capacitive element; can optionally include that the further voltage-variable capacitive element and the further driver are provided in a differential signal path that is different from a signal path in which the voltage-variable capacitive element and the driver are provided.

In example 27, the subject matter of example 26, may further include a further transformer-based matching network may include a transformer with a primary winding coupled to the further output terminal; can optionally include that the primary winding of the further transformer-based matching network includes a center tap; can optionally include that the voltage supply circuit further is coupled to the center tap of the primary winding of the further transformer-based matching network.

In example 28, the subject matter of any one of examples 22 to 27, can optionally include that the supply voltage is to control capacitance of at least one circuit of the plurality of circuits.

In example 29, the subject matter of example any one of examples 22 to 25, can optionally include that the controller is further configured to control the voltage supply circuit.

In example 30, the subject matter of any one of examples 22 to 29, can optionally include that the controller is configured to control the supply voltage based on a frequency band of radio frequency (RF) signals; can optionally include that the frequency band of RF signals includes at least one of 2.4 GHZ, 5 GHZ, or 6 GHZ.

In example 31, the subject matter of example 31, can optionally include that the controller is configured to cause the voltage supply circuit to supply a first voltage for one of the frequency bands of RF signals and to cause the voltage supply circuit to supply a second voltage for another one of the frequency band of RF signals.

In example 32, the subject matter of any one of examples 16 to 31, may further include an antenna port configured to receive output signals of the CDAC.

In example 33, the subject matter of any one of examples 16 to 32, can optionally include that the apparatus is a digital polar transmitter.

In example 34, the subject matter includes an apparatus of a digital communication circuit. the apparatus may include: a plurality of capacitive digital-to-analog converter (CDAC) cells configured to receive a digital signal to be converted to an analog signal, each CDAC cell includes: a variable capacitive element; and an inverter coupled to the variable capacitive element, the inverter is configured to invert the received digital signal to drive the variable capacitive element to convert the received digital signal to the analog signal.

In example 35, The apparatus of example 35, can optionally include that the apparatus is further configured to operate in accordance with various aspects described in this disclosure, in particular any one of examples 1 to 33.

In example 36, the subject matter includes a capacitive digital-to-analog converter (CDAC). The subject matter may include: a plurality of circuits for receiving a digital signal to be converted into an analog signal, can optionally include that each circuit of the plurality of circuits includes: a variable capacitive component; and a driver means for causing the variable capacitive component to be charged or discharged to convert the received digital signal into the analog signal.

In example 37, the subject matter of example 36, can optionally include that each circuit further includes: a logic means for providing the received digital signal to a signal path coupled to the driver based on a received control signal.

In example 38, the subject matter of example 36 or example 37, can optionally include that the CDAC includes an output means coupled to the variable capacitive component of each circuit; can optionally include that the variable capacitive component is a voltage-variable capacitive component.

In example 39, the subject matter of example 38, can optionally include that a capacitance of the voltage-variable capacitive components is controlled by a voltage applied to the output terminal.

In example 40, the subject matter of example 39, can optionally include that the driver means includes an inverting means.

In example 41, the subject matter of example 40, can optionally include that the inverting means is for providing an inverted digital signal varying between an upper voltage level and a lower voltage level; can optionally include that the voltage applied to the output terminal is at the upper voltage level.

In example 42, the subject matter of example 40, can optionally include that the inverting means is for providing an inverted digital signal varying between an upper voltage level and a lower voltage level; can optionally include that the voltage applied to the output terminal is at the lower voltage level.

In example 43, the subject matter of any one of examples 38 to 42, can optionally include that the voltage-variable capacitive component includes a metal oxide semiconductor (MOS) varactor.

In example 44, the subject matter of any one of examples 38 to 43, can optionally include that the received digital signal includes a first digital signal and a second digital signal that is a differential pair of the first digital signal; can optionally include that the variable capacitive component is a first variable capacitive component, and the output terminal is a first output terminal; can optionally include that the CDAC further includes a second voltage-variable capacitive component coupled to a second output terminal to convert the second digital signal into the analog signal.

In example 45, the subject matter of example 44, may further include a further driver means configured to cause the further voltage-variable capacitive component to be charged or discharged based on the second digital signal.

In example 46, the subject matter of example 10, can optionally include that a capacitance of the further voltage-variable capacitive component is controlled by a voltage applied to the second output terminal.

In example 47, the subject matter of example 11, can optionally include that the voltage applied to the first output terminal and the voltage applied to the second output terminal are equal.

In example 48, the subject matter of any one of examples 10 to 12, may further include: a further logic means for providing the second digital signal to a second signal path coupled to the further driver.

In example 49, the subject matter of example 13, can optionally include that the logic component and the further logic component is controlled by the same control signal.

In example 50, the subject matter of any one of examples 1 to 14, can optionally include that received digital signal includes an oscillator signal.

In example 51, the subject matter includes an apparatus of a digital communication circuit. The subject may include: a capacitive digital-to-analog converter (CDAC) may include: a plurality of circuits for receiving a digital signal to be converted into an analog signal, can optionally include that each circuit of the plurality of circuits includes: a variable capacitive component; a driver means for causing the variable capacitive component to be charged or discharged to convert the received digital signal into the analog signal; and a controller for activating or deactivating each circuit of the plurality of circuits.

In example 52, the subject matter of example 51, can optionally include that the controller is for activating or deactivating each circuit of the plurality of circuits based on amplitude control information.

In example 53, the subject matter of example 52, may further include: a digital front end for providing the amplitude control information based on baseband signals.

In example 54, the subject matter of example 52 or example 53, may further include: an oscillator for generating an oscillator signal; a digital-to-time converter for modulating generated oscillator signal based on phase control information.

In example 55, the subject matter of example 54, can optionally include that the digital front end is for providing the phase control information based on the baseband signals.

In example 56, the subject matter of any one of examples 51 to 55, can optionally include that the variable capacitive component is a voltage-variable capacitive component; can optionally include that the voltage-variable capacitive components of the plurality of circuits are coupled to an output terminal; can optionally include that the apparatus further includes a transformer-based matching network may include a transformer with a primary winding coupled to the output terminal.

In example 57, the subject matter of example 56, may further include: a voltage supply means for supplying a voltage to the output terminal.

In example 58, the subject matter of example 57, can optionally include that the primary winding of the transformer includes a center tap, and can optionally include that the voltage supply circuit is for supplying the voltage to the center tap.

In example 59, the subject matter of example 58, can optionally include that the driver means is for providing a driver signal varying between an upper voltage level and a lower voltage level; can optionally include that the supply voltage is at the upper voltage level.

In example 60, the subject matter of example 58, can optionally include that the driver means is for providing a driver signal varying between an upper voltage level and a lower voltage level; can optionally include that the supply voltage is at the lower voltage level.

In example 61, the subject matter of example any one of examples 57 to 60, can optionally include that each circuit further includes a further voltage-variable capacitive component for discharging to a further output terminal, and a further driver for driving the further voltage-variable capacitive component; can optionally include that the further voltage-variable capacitive component and the further driver are provided in a differential signal path that is different from a signal path in which the voltage-variable capacitive component and the driver are provided.

In example 62, the subject matter of example 61, may further include a further transformer-based matching network may include a transformer with a primary winding coupled to the further output terminal; can optionally include that the primary winding of the further transformer-based matching network includes a center tap; can optionally include that the voltage supply circuit further is coupled to the center tap of the primary winding of the further transformer-based matching network.

In example 63, the subject matter of any one of examples 57 to 62, can optionally include that the supply voltage is to control capacitance of at least one circuit of the plurality of circuits.

In example 64, the subject matter of example any one of examples 57 to 62, can optionally include that the controller is for controlling the voltage supply circuit.

In example 65, the subject matter of any one of examples 57 to 64, can optionally include that the controller is for controlling the supply voltage based on a frequency band of radio frequency (RF) signals; can optionally include that the frequency band of RF signals includes at least one of 2.4 GHZ, 5 GHZ, 6 GHZ, or 7 GHZ.

In example 66, the subject matter of example 65, can optionally include that the controller is for causing the voltage supply circuit to supply a first voltage for one of the frequency bands of RF signals and to cause the voltage supply circuit to supply a second voltage for another one of the frequency bands of RF signals.

In example 67, the subject matter of any one of examples 51 to 66, may further include an antenna port for receiving output signals of the CDAC.

In example 68, the subject matter of any one of examples 51 to 67, can optionally include that the apparatus is a digital polar transmitter.

In example 69, a controller may include a processor, the processor is configured to: determine to vary capacitance of unit cells of a switched capacitor radio frequency (RF) digital to analog converter, and control a voltage supply circuit to vary the capacitance of the unit cells of the switched capacitor RF digital to analog converter based on the determination.

In example 70, the controller of example 69 may further be configured to perform any operations provided in this disclosure, in particular the operations described for a controller or a processor in the disclosure.

What is claimed is:

1. A capacitive digital-to-analog converter (CDAC) comprising:
a plurality of circuits configured to receive a digital signal to be converted into an analog signal, wherein each circuit of the plurality of circuits comprises:
a variable capacitive element; and
a driver configured to cause the variable capacitive element to be charged or discharged to convert the digital signal into the analog signal.

2. The CDAC of claim 1,
wherein each circuit further comprises a logic component configured to provide received digital signal to a signal path coupled to the driver based on a received control signal.

3. The CDAC of claim 1,
wherein the CDAC comprises an output terminal coupled to the variable capacitive element of each circuit,
wherein the variable capacitive element is a voltage-variable capacitive element.

4. The CDAC of claim 3,
wherein a capacitance of the voltage-variable capacitive elements is controlled by a voltage applied to the output terminal.

5. The CDAC of claim 4,
wherein the driver comprises an inverter,
wherein the inverter is configured to provide an inverted digital signal varying between an upper voltage level and a lower voltage level,
wherein the voltage applied to the output terminal is at the upper voltage level.

6. The CDAC of claim 4,
wherein the driver comprises an inverter,
wherein the inverter is configured to provide an inverted digital signal varying between an upper voltage level and a lower voltage level,
wherein the voltage applied to the output terminal is at the lower voltage level.

7. The CDAC of claim 3,
wherein the voltage-variable capacitive element comprises a metal oxide semiconductor (MOS) varactor.

8. An apparatus of a digital communication circuit, the apparatus comprising:
a controller; and
a capacitive digital-to-analog converter (CDAC) comprising a plurality of circuits configured to receive a digital signal to be converted into an analog signal, wherein each circuit of the plurality of circuits comprises:
a variable capacitive element;
a driver configured to cause the variable capacitive element to be charged or discharged to convert the digital signal into the analog signal,
wherein the controller is configured activate or deactivate each circuit of the plurality of circuits.

9. The apparatus of claim 8, wherein the controller is configured to activate or deactivate each circuit of the plurality of circuits based on amplitude control information.

10. The apparatus of claim 8, further comprising:
a digital front end configured to provide the amplitude control information based on baseband signals.

11. The apparatus of claim 8,
wherein each circuit further comprises a further voltage-variable capacitive element configured to discharge to a further output terminal, and a further driver configured to drive the further voltage-variable capacitive element,
wherein the further voltage-variable capacitive element and the further driver are provided in a differential signal path that is different from a signal path in which the voltage-variable capacitive element and the driver are provided.

12. The apparatus of claim 8, wherein the variable capacitive element is a voltage-variable capacitive element,
wherein the voltage-variable capacitive elements of the plurality of circuits are coupled to an output terminal,
wherein the apparatus further comprises a transformer-based matching network comprising a transformer with a primary winding coupled to the output terminal.

13. The apparatus of claim 12, further comprising:
a voltage supply circuit configured to supply a voltage to the output terminal.

14. The apparatus of claim 13, further comprising:
a transformer coupled to the output terminal,
wherein a primary winding of the transformer comprises a center tap, and wherein the voltage supply circuit is configured to supply the voltage to the center tap.

15. The apparatus of claim 13,
wherein the voltage causes to control capacitance of at least one circuit of the plurality of circuits.

16. The apparatus of claim 13,
wherein the controller is further configured to control the voltage supply circuit.

17. The apparatus of claim 16,
wherein the controller is configured to control the supply voltage based on a frequency band of radio frequency (RF) signals,
wherein the frequency band of RF signals comprises at least one of 2.4 GHz, 5 GHZ, or 6 GHz.

18. The apparatus of claim 17,
wherein the controller is configured to cause the voltage supply circuit to supply a first voltage for one of the frequency bands of RF signals and to cause the voltage supply circuit to supply a second voltage for another one of the frequency bands of RF signals.

19. The apparatus of claim 8, further comprising an antenna port configured to receive output signals of the CDAC.

20. The apparatus of claim 8, wherein the apparatus is a digital polar transmitter.
